(19) United States
(12) Patent Application Publication
(10) Pub. No.: US 2003/0217766 A1
(43) Pub. Date: Nov. 27, 2003

(54) Torus semiconductor thermoelectric device

(76) Inventors: Jon Murray Schroeder, Cedar Park, TX (US); Gerald Phillip Hirsch, Pine Bluff, AR (US)

Correspondence Address: Jon Murray Schroeder, Suite # 148-323, 100 E. Whitestone Blvd., Cedar Park, TX, 78613, US

(21) Appl. No.: 10/154,757

(22) Filed: May 23, 2002

(51) Int. Cl. H01L 31/058; H01L 35/00

(52) U.S. Cl. 136/230; 136/212; 257/467

(57) ABSTRACT

An improved torus multi-element semiconductor thermoelectric hybrid utilizes a make-before-break high frequency switching output component to provide nominal alternating current voltage outputs. Overall efficiency of heat conversion is improved by coupling a chiller to the thermoelectric generator where exhaust heat produces chilled liquid or air that is conveyed to the cold side of the thermoelectric device.

### TECHNICAL FIELD

This invention relates to a circular array of semiconductor and conductive elements that comprise a thermoelectric device. Energy generated by a temperature differential between hot and cold fins of the thermoelectric device is more efficiently converted to electrical energy by a high frequency switching component. Fuel efficiency is improved by insulating a reflecting cover over the burner unit. Improved energy conversion efficiency is obtained by combining a chiller unit with the thermoelectric device taking the excess heat from the burner to produce cold air or liquid and using the cold air or liquid to cool the cold fins of the thermoelectric device.

### BACKGROUND ART

Thermoelectric devices have been used for many years for specific applications where the simplicity of design warrants their use despite a low energy conversion efficiency.

The voltage produced by a thermoelectric device depends on the Seebeck voltage of the dissimilar metals used. Seebeck voltages are higher for some semiconductor materials especially n-type and p-type elements made primarily of mixtures bismuth, tellurium, antimony.

To compete with more traditional forms of heat to electricity conversion thermoelectric devices must be as efficient as possible. A preferred means to achieve such high efficiency is to arrange the thermoelectric element in a circle with only a very small region used to extract the energy produced by the thermoelectric elements. Patent PCT/US97/07922 to Schroeder discloses such a circular arrangement. Art teaching in this case focused on 3 means to extract energy for the high current in the ring of elements; 1—a vibrating mechanical switch, 2—a Hall effect generator and 3—a Colpits oscillator. Coatings of hot and cold elements of the thermoelectric device are claimed for selenium, tellurium and antimony among others but not for mixtures of these elements.

U.S. Pat. No. 6,222,242 to Konishi, et al. discloses semiconductor material of the formula AB.sub.2, X.sub.4 where A is one of or a mixture of Pb, Sn, or Ge, B is one of or a mixture of Bi and Sb and X is one of or a mixture of Te and Se. These represent Pb, Sn or Ge doped bismuth telluride.

U.S. Pat. No. 6,274,802 to Fukuda, describes a sintering method of making semiconductor material whose principle components include bismuth, tellurium and selenium and antimony.

U.S. Pat. No. 6,340,787 to Simeray discloses a thermoelectric component of bismuth doped with antimony and bismuth tellurium doped selenium wherein said component are arranged into a rod. Very low voltages are converted using a self-oscillating circuit.

U.S. Pat. No. 6,172,427 describes the use of a thermoelectric device on the exhaust portion of a combustion-based car using electrically drive wheel wherein excess heat energy is converted to electric power for the vehicle.

It is a purpose if this invention to provide improved efficiency for the conversion of heat energy to electrical energy by making use of n-doped and p-doped semiconductors attached to metal heat-conducting elements in a circular arrangement of thermoelectric components.

It is a further purpose of this invention to provide a high efficiency of transmission of energy contained in a thermoelectric torus to AC current at desired voltages by utilizing a make-before-break high frequency circuit.

Another purpose of this invention is to improve the efficiency of said thermoelectric device by combining it with a chiller. Excess heat from the thermoelectric is transferred to the chiller where it is converted to cold air or liquid. The cold air or liquid is then transported to the cold fins of the thermoelectric device where by lowering the temperature of the cold fins improves the voltage for a given heating arrangement.

It is a purpose of this invention to provide an efficient device to convert a variety of heat sources to electricity.

### DISCLOSURE OF THE INVENTION

To illustrate this invention figures are drawn to show components of a few implementations of the invention. It should be understood that these figures do not in any way limit this invention as describe in the claims.

The invention comprises a heat source, a plurality of thermoelectric coupons arranged in a ring, a means for extracting electrical energy from said ring. Energy is produced in the form of current circling through a plurality of coupons. This current is induced when hot and cold fins of the thermoelectric coupons are respectfully heated or cooled or allowed to cool in the case of cold fins. The term coupon is used herein to identify the combination of hot fins, cold fins and constituents attached thereto. Multiple coupons are assembled to make a ring. The ring conformation is important in reducing losses that would otherwise occur if a conductor were used to electrically connect ends of a linear array of coupons.

The heat source can be any of a myriad of combustible materials such as gasses of hydrogen, methane, ethane, propane, butane, etc, liquids such as gasoline, kerosene or crude oil, and solids such as wood, used tires, straw and other celluloid materials and coal. In addition the heat needed for electricity production can come from concentrated sunlight. Waste heat from other combustion activities can also be used.

For several means used to generate heat, the hot gasses are passed over the hot fins to heat them. In a preferred embodiment gas or liquid is combusted directly under the hot fins. In a preferred configuration the hot fins project inward with regard to a circle or torus of coupons and the hot gas is passes through or combustion occurs adjacent to the hot fins.

In another preferred embodiment the rate of fuel combustion is controlled to match the electrical demand of the thermoelectric device.

In the case of gas or liquid being combusted near the hot fins infrared radiation which passes through or is given off from the hot fins is radiated back on the hot fins by a reflective metallic dome.

In another preferred embodiment the reflective dome is backed by an insulating layer.

In one form of the invention an opening is made in the top dome to allow hot gas to escape.

A preferred embodiment of the invention is to combine a chiller with the thermoelectric device. Hot gases escaping from the thermoelectric device are conveyed or allow to move into the chiller. The chiller uses the hot gas to produce cold air or liquid. The cold air or liquid is then directed back to the cold fins of the thermoelectric device. By cooling the cold fins the temperature differential between the hot fins and cold fins is increased producing greater voltage in each coupon and therefore more energy to be extracted from the thermoelectric portion of the combined system.

A unique method is used to extract energy from the high current flowing in the thermoelectric device. An insulator is used to force current into a means for extracting electrical energy. This insulator is place between any two coupons. On each side of the insulator is a conductor which extends outward from the torus of coupons. The conductor is divided in half with one half being wound around the center core of a transformer in one direction and the other half being wound in the opposite direction. To control current flow in one or the other direction MOSfet switches are inserted in the circuit of the primary winding taken from the ring of coupons. The number of chips employed in parallel is determined by the maximum amount of current generated in the ring and depends on the capacity of the MOSfet switches.

In a preferred embodiment a pulse-width modulator chip is used to control the MOSfet switches. If a simple oscillating circuit is used optimum power is not obtained. If the pulse-width modulator is not used very high spikes of current are induced in the primary and secondary. Such spikes would adversely affect electric devices that use the secondary voltage outputs.

Secondary windings in the outer portion of said transformer produce desired output AC voltages. The number of windings needed depend on the current in the ring and the efficiency of extracting that energy. The number of windings needed can be determined by those skilled in the electronic arts.

Conversion of heat to electricity is improved in a closed loop thermoelectric device by utilizing a combination of n-type and p-type semiconductors. These produce a high Seebeck effect thereby producing a higher voltage output for a given thermal differential.

Tight junctions, very low levels of contaminating elements and special surfaces are required to produce a uniform device for high levels of conversion of heat to electrical energy.

Getting alternating current energy out of a circle of thermoelectric elements or coupons requires special conversion components. An important component involved in the extraction of electrical energy is a make-before-break control circuit, which prevents damaging high voltage spikes during current switching.

The device disclosed herein has greater conversion efficiency than the traditional systems currently in use, such as a steam generator.

This thermoelectric device is very quiet when running thus providing an opportunity to replace noisy gas driven implements and appliances.

To provide these benefits details are given for making and using a simple circular collection of coupons. Each coupon is made by alternating a hot fin that is a metal fin to be heated, an n-type semi conductor, then a cold fin, that is a fin to be cooled or allowed to cool, then a p-type semiconductor. Such coupons are place in registry, that is hot fin, n-type, cold fin, p-type, hot fin, n-type, cold fin, p-type and so on until a circle is completed. When the fins are made flat a wedge piece is added to produce continuity to the circle. A single insulator is placed in the circle across which current is removed as desired. A voltage is produced when hot fins are heated. This voltage is proportional to the temperature differential between heated hot fins and cold fins and the number of coupons. For some applications the voltage produced is used directly. To produce alternating current a controller is placed across the insulator and windings around the central and secondary portions a ferrite core allow production of a desired voltage and frequency.

For clarity of the disclosure and definition of the claims the following terms are defined: “Semiconductor” means: a mixture of one or more elements that has the property of allowing either electrons or holes to move through the mixture depending on whether the mixture has an excess n-type or p-type dopant. The semiconductor nature of thermoelectric wafers is well established in the thermoelectric literature. “Fin” means: an elongated metal slab with optional tapered ends which are connected on one side to an n-type semiconductor and on the other side to a p-type semiconductor or on either side to a conductive wedge. “Cold fin” means: a fin to be cooled or a fin to be allowed to cooled. “Hot fin” means: a fin that is to be heated. “Coupon” means a repeating component of the thermoelectric device made up of at least one n-type semiconductor, one hot fin one p-type semiconductor, and one cold fin. In the device having a wedge component with each set of fins and semiconductors a coupon includes the wedge component. “Kester's solder” means: lead free solder paste containing tin, copper and silver. “Belleville disk spring” means: deflecting washers that maintain constant compressive pressure through thermal expansion and contraction of other members. “Wafer” means: an n-type or p-type semiconductor made in the shape of thin slab where the thickness of the shortest dimension is from 1% to 20% of the either of the other dimensions.

“Wafer side” means: the surface area denoted by the larger dimension of a wafer.

“Wafer edge” means: the surface area denoted by the smallest dimension and one or the other dimensions.

is Before describing how to produce components of the invention figures are provided that illustrate such a working version. Example are intended to illustrate the basic principles and elements of the device and is in no way is intended to limit the scope of the invention as described in the claims.

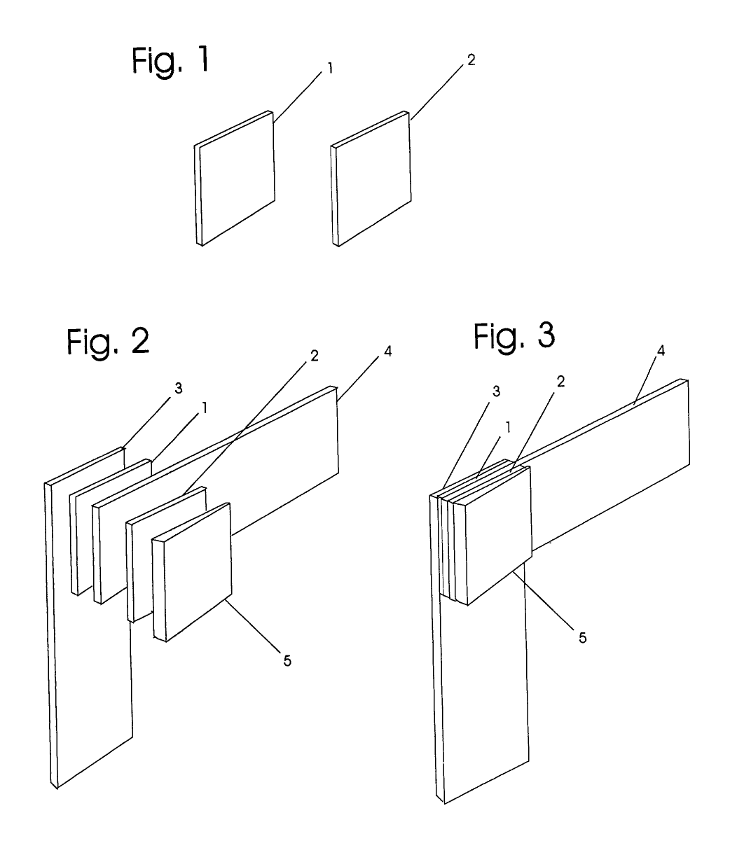

FIG. 1 illustrates a p-type 1 and an n-type 2, crystalline wafer. In a preferred embodiment these wafers are replaced by direct application of the n-type or p-type semiconductor material directly on either the hot fin or the cold fin.

FIG. 2 illustrates a cold fin 3, a hot fin 4, a p-type crystalline wafer 1 and an n-type crystalline wafer 2 along with a wedge 5 that comprise a coupon of the invention. FIG. 2 illustrates an exploded view of the elements of the coupon and the relative position they will occupy when they are assembled as a complete coupon. N-type crystalline wafer 1 positions to cold fin 3, which has a layer of solder paste in the region where the n-type wafer 2 will bond to cold fin 3. Hot fin 4 has solder paste in the regions that will bond it to wafer 1 and p-type wafer 2. Wafer 2 bonds with solder paste to the wedge 5 on one side.

FIG. 3 illustrates the final positions of the elements of the coupon seen in FIG. 1, 62 of these coupons needed in the completed thermoelectric ring. This number can be varied depending on the operating voltage desired. The Seebeck voltage also effects how much voltage is produced for a give temperature differential between the hot and cold fins. It should be understood that the cold fins need not be directed at 90 degrees to the hot fins. Furthermore it is possible to fashion the shape of either the hot fin or the cold fin or both to preclude the need for the wedge component.

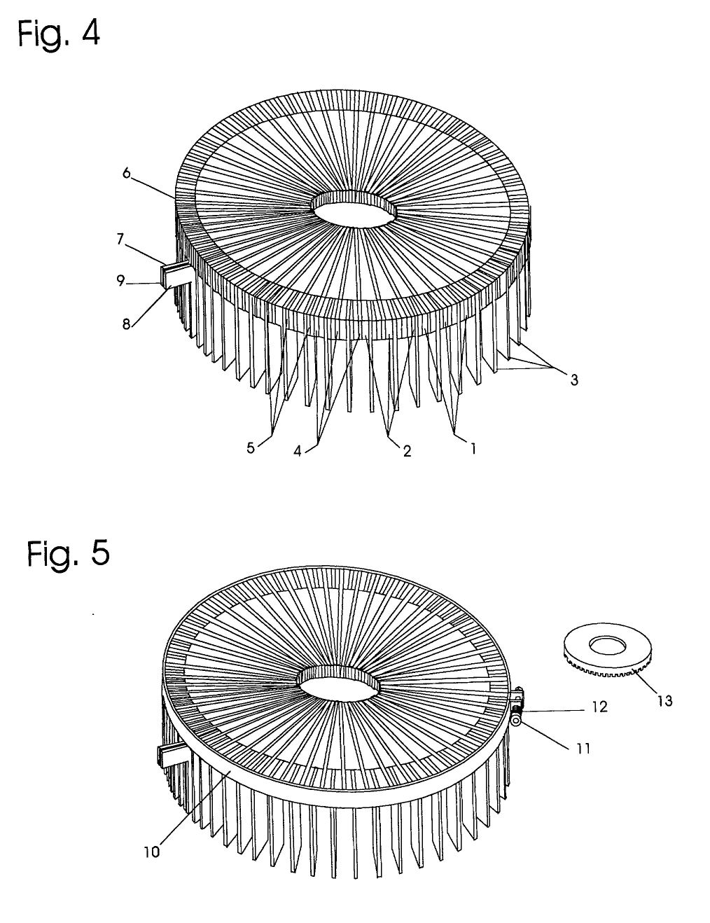

FIG. 4 illustrates the assembled thermoelectric ring 6, made up of 62 coupons of FIG. 3, along with two special cold fins 7 and 8. One of these is an extra cold fin use to allow a cold fin rather than a hot fin for connection to the up-converter. These cold fins are separated by an insulator preferably a mica insulator, 9. The purpose of the cold fins and mica is to provide terminals for up-converter connections. The mica insulator breaks the electrical circuit of the ring and allows the current produced by the ring and flow into the center tap of the up-converter's primary winding in the direction the control circuit directs. In FIG. 4, the cold fin 3, the p-type wafer 1, the hot fin 4, the n-type wafer 2, and the wedge 5 can be seen in their assembled position, like coupons repeating all the way around the ring with the single interruption of the substitution of two cold fins 7 and 8 separated by insulator 9.

FIG. 5 illustrates how the strap 10 fits around the top portion of the ring to compress the elements by the tensioning of the strap with bolt 11. The tension on the strap, and likewise the compression of the elements is maintained at operating temperatures as well as at ambient temperature by a series of Bellville washers 12, compression maintained at approximately 500 pounds on the strap 10. In FIG. 5, ceramic part 13 fills the hole at the center tips of the hot fins and causes heat to exhaust between the hot fins instead of passing through the hole. This optional component can be made of any non-conductive, non-combustible material. In a preferred embodiment the ceramic part is cast with groves which can accommodate the end of the hot fins thereby stabilizing these fins.

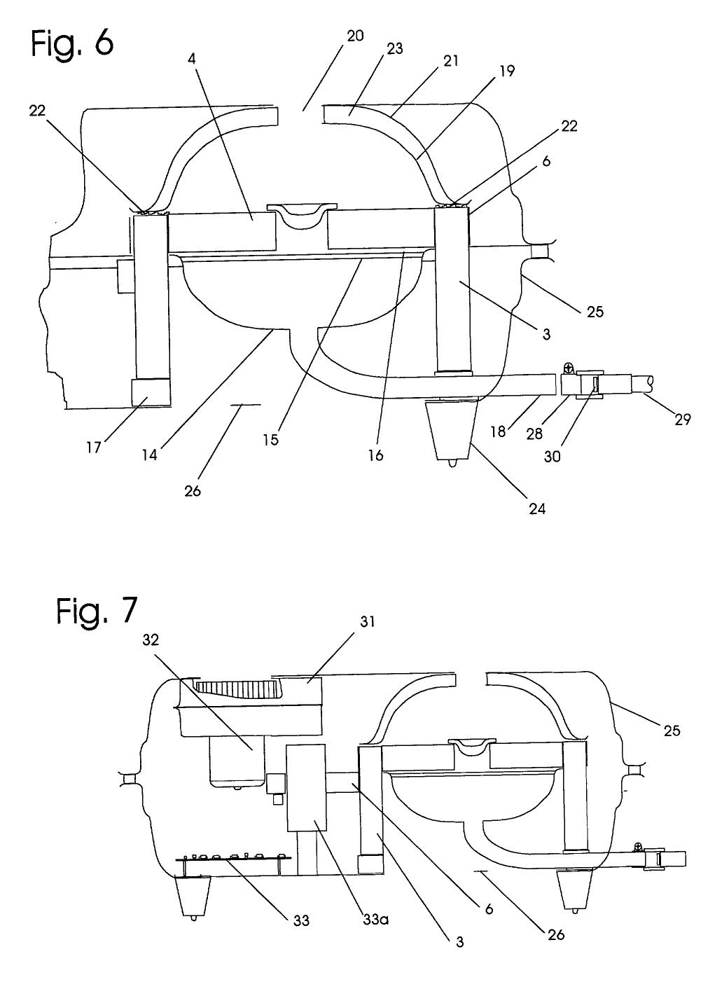

FIG. 6 illustrates a cross section of a gas or liquid combustion version of generator invention. 14 shows a burner bowl with attached perforated metal 15 that holds a mesh 16. This serves to prevent incoming air-fuel mixture from combusting before entering the combustion chamber. Inlet pipe 18 allows the air-fuel mixture to enter the burner bowl. Support ring 17, an insulator, lifts the generator ring so that burner pipe 18 can pass underneath without having to shorten any of the cooling fins 3. 19 is a top burner bowl with an exhaust hole 20 that is attached to the ring 6. 21 is a larger, outer bowl that serves to give the welded-together, double-bowel combination structural integrity, important to maintain the thermoelectric ring in a circle, thus preventing it from going egg-shaped and failing in the electrical conductivity mode. Welded together bowls 19 and 21 are bonded to ring 6 with room temperature vulcanizing rubber 22, such as General Electric high temperature silicone adhesive. This material is also used to attach the cold fins 3 to the supporting ring 17. 23 is thermal insulation material to maintain bowl 19 hot, 21 cool so as to radiate as much heat from the burner screen 16 back on the hot fins 4 as possible, thereby increasing power output for the generator. 24 is one of four legs that raise the case 25 off the floor so cooling air can exhaust from hole 26 freely. Legs 24 secure the burner pipe 18 that connects the fuel hose 29 to the burner orifice 30. The purpose of the burner orifice 30 is to meter fuel to the burner at an adjustable fuel pressure and to cause air to enter burner pipe 18 at the correct air-fuel mixture. Also in FIG. 6, the metal case 25, reduces electromagnetic interference of the high frequency aspects of the generator is shown. Not shown is a means to ignite the fuel at the desired place. In a preferred embodiment an ignition spark means just above screen 16 is used. Alternatively the fuel can be initially ignited manually.

FIG. 6 illustrates one implementation of the thermoelectric device for burning gas or liquid fuel. When other sources of heat are available, such as steam, the burner portion of the device is replaced with a means from exposing the hot fins to said heat source. Alternatively bowl 14 can be designed to have metal 15 and mesh 16 place near the bottom of bowl 14 and a means provided for placing solid fuel between mesh 16 and hot fins 4.

FIG. 7 illustrates an air blower 31 open to the top and driven by motor 32. The motor is powered by an electronic circuit board 33, that derives power from the up-converter 33a attached to the thermoelectric ring 6. Air enters the case 25 through blower31 and is directed towards the thermoelectric ring, flowing as a vortex, cooling the electronic board 33 and up-converter 33a and finally exiting through the cold fins 3 and through bottom hole 26 to the outside of case 25.

FIGS. 1 through 7 illustrate a preferred form of this invention being a table-top type arrangement. It should be understood that the general nature of the thermoelectric device can be fitted to many forms and sizes. For example the arrangement describe can be made to be carried in a back pack allowing the user to carry around a source of 120/240 volt alternating current. Such a backpack would allow the use of tools that normally run on alternating current. Still smaller versions could be used to replace a battery pack. Such a backpack version could replace rechargeable batteries and be used with existing rechargeable battery tools.

In a preferred embodiment a hybrid thermoelectric device and mechanical tool is constructed which comprises an electric motor to drive the mechanical tool. An advantage of the hybrid tool is that feedback from the tool can be used to control the rate that fuel is burned. In another preferred embodiment a general version of said hybrid tool has a uniform thermoelectric component that is fitted to a variety of mechanical components. This feature allows a single thermoelectric component to be exchanged among several tool types.

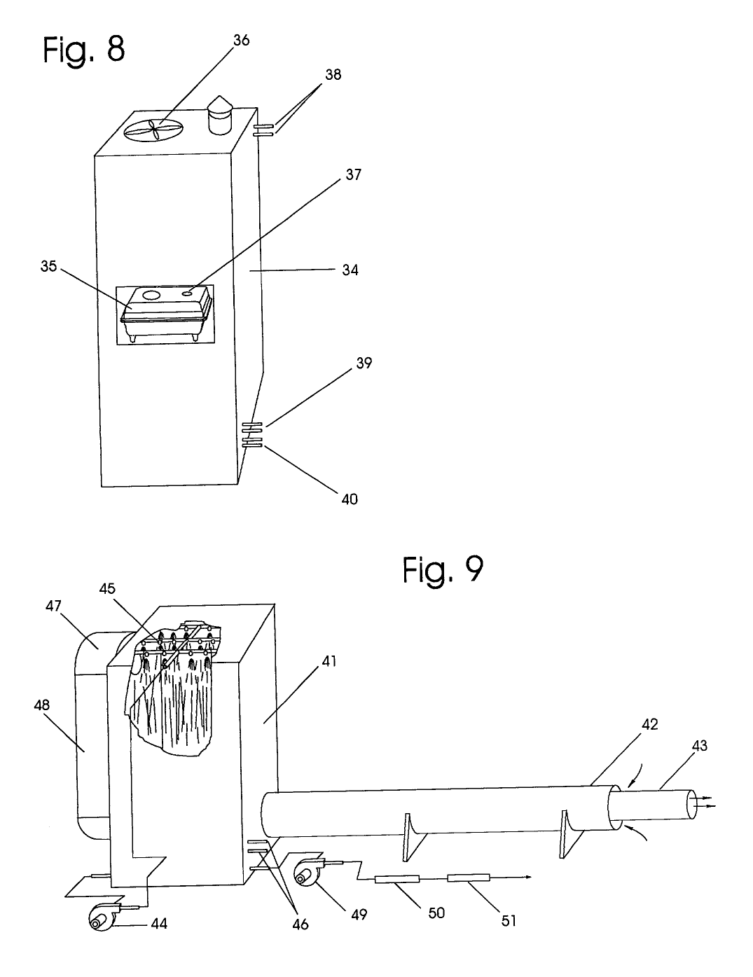

FIG. 8 illustrates a heat-powered absorption chiller 34, in this case heated by the exhaust gas from the thermoelectric generator 35 that brings in air. 36 is a exhaust fan that is driven by generator 35. Chiller 34 has a grill not show that allow air to enter the case of chiller 34. 37 is the exhaust gas coming from the generator 35 that then passes through the absorption chiller 34, causing it to produce a chilling effect. 38 is an optional inlet/outlet of a low quality heating loop useful for heating hot water in a home, office or manufacturing process. 39 is the quality heating fluid loop that can be used to heat an environment or to waste this heat to the environment when the chiller requires this for maximum refrigeration effect. 40 is the chilled fluid loop that can be used to air condition a home, office or industrial building. All or a portion of chilled fluid can be transferred to cool the cold fins. In a preferred embodiment cold fins are placed in an enclosed non-conductive torus being seal where said cold fins enter the torus. Chilled liquid from the chiller passes into and out of the enclosed torus. FIG. 8 shows the self-containment feature of the self-powered chiller appliance. It is possible to adjust hot air flow so that one third of the heat of the fuel that powers this appliance makes electricity to operate the chiller and also the complete household, while reusing this heat stream to heat hot water for the home. The remaining two-thirds of the heat powers the absorption chiller to air condition or heat the household. In a preferred embodiment not shown a means is provided to allow some of the heat of combustion to be taken from 14 directly to the chiller without passing over hot fins 4. This feature allows the chiller to operate when there is little need for electricity.

FIG. 9 illustrates a chill box 41. This appliance operates with the self-powered chiller of FIG. 8, using some or all of the refrigeration effect to harvest water. This appliance can harvest water from the air for drinking purposes, sanitation, to irrigate lawns and even agriculture. 42 shows an air-inlet pipe for the chill box 41, passing over outlet air in pipe 43. This counter flow method conserves on overall chilling power that is needed. 44 shows a pump that circulates chilled water to nozzle set 45, that sprays water chilled from the chiller 34 in FIG. 8 through cooling loop 46 to fall and mix with incoming air from pipe 42. The chilled droplets condense water from supersaturated air and deposit it with the fine droplets to the bottom of chill box 41 where it is re-circulated to nozzles 45, by pump 44. 47 is an air blower that pulls cooled air from chill box 41 and pushes it down through tube 48, and through the outlet tube 43 while cooling air that is incoming through tube 47. 49 is a pump that removes harvested water and pushes it through 50 which is an ultraviolet system to kill germs, then through filter 51 which removes the particulate before transferring the pure water to a storage tank. Other means of sterilizing water may be used. This water harvesting system can use most or any portion of the self-powered chiller's capacity depending on the priority for water, cooling for the living environment or to meet electrical requirements.

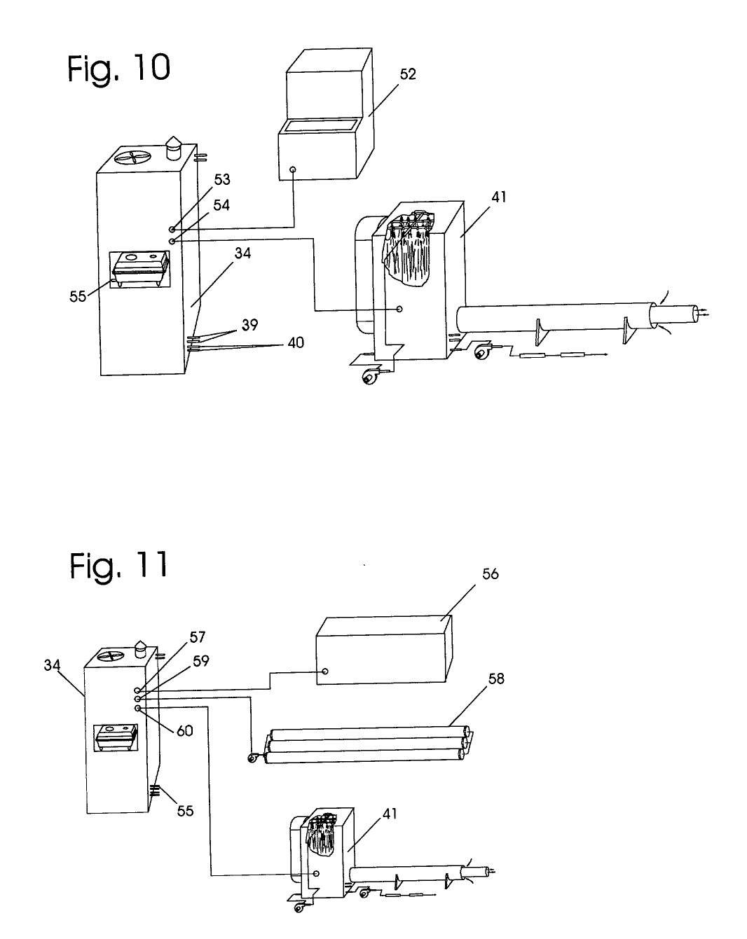

FIG. 10 illustrates how the self powered chiller invention 34 works with an ice-making machine 52 and an air dehumidifier, water-harvesting machine 41. Both machines 52 and 41 derive their refrigeration using chilled fluid loop 40. Both machines 52 and 41 derive their electrical power from the self-powered chiller 34 by way of electrical connections 53 and 54. Heat is wasted to the ambient in heating loop 39, or it is used for another useful process such as heat a building, swimming pool or to dry agricultural product. The combination invention described in FIG. 10 makes electricity, makes water, and makes ice of the water. In addition, it can heat enclosures and dry crops for safe storage and transportation, all with the same fuel stream 55.

FIG. 11 illustrates how the invention is used to drive an electro-dialysis machine 56 for converting brackish water into pure potable water using electrical connection 57 to self-powered chiller 34. In addition, it illustrates how the self-powered chiller can operate a reverse osmosis 58 that makes potable water of seawater with electrical power through electrical connection 59. In addition, FIG. 11 illustrates how the self-powered chiller can operate a dehumidifying chiller box 41 that uses electrical connection 60 and cooling loop 55. Anyone or all of the appliances 56, 58 or 41 can be used individually, as a pair or simultaneously to process water for drinking, sanitation and or to promote agriculture.

FIG. 12 illustrates ammonia production using the invention. The self-powered chiller 34 with generator 35, supplies power to make hydrogen from water in a dissociation machine 61. Electrical connection 62 is used to power the hydrogen machine 61. The hydrogen gas passes through flow meter 63. Nitrogen can be made in a pressurizing machine 64 that uses a process of compressing and then refrigeration using the cooling loop 46 to separate and collect nitrogen, removing oxygen, with the self-powered chiller 34. Electrical connection 65 is used to power the nitrogen machine 64. Nitrogen gas is measured in flow meter 66, after which it combines with measured ratio of hydrogen and bubbled to combine together in tank 67 as ammonia, or optionally dissolved in water, and used as fertilizer for agriculture. Pump 68 transfers' ammonia to a mobile tank that can be towed to the field in cart 69 for use in agricultural irrigation water or used directly in the subsurface plowing of crops. FIG. 12 illustrates how the invention can be used to produce a product that is useful in agriculture, at the same time supplying the electrical, heating and cooling needs of a home, farm or rural village, all with the same fuel stream 55.

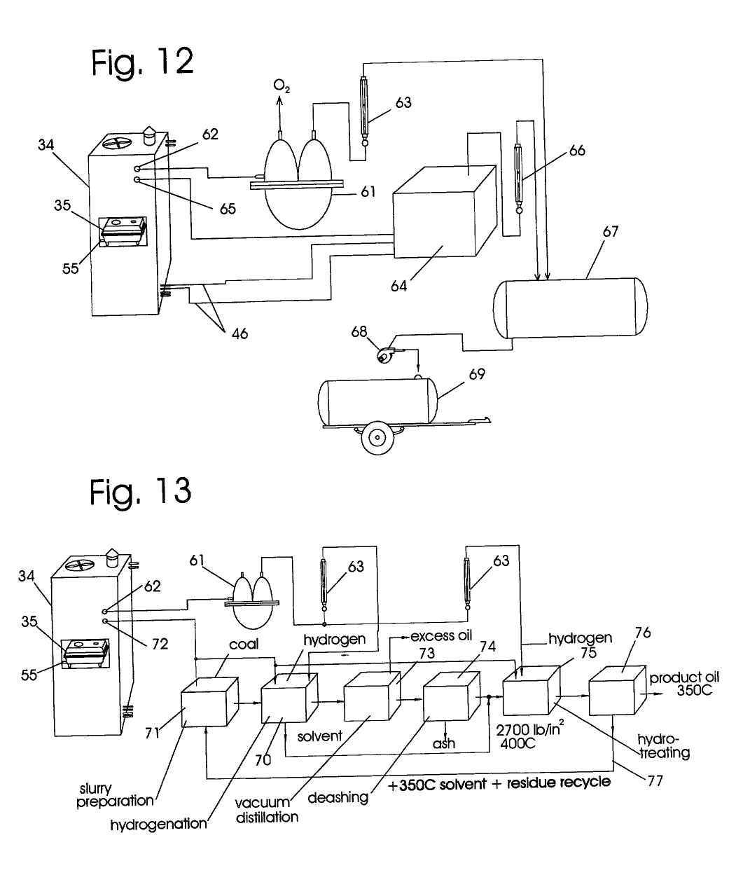

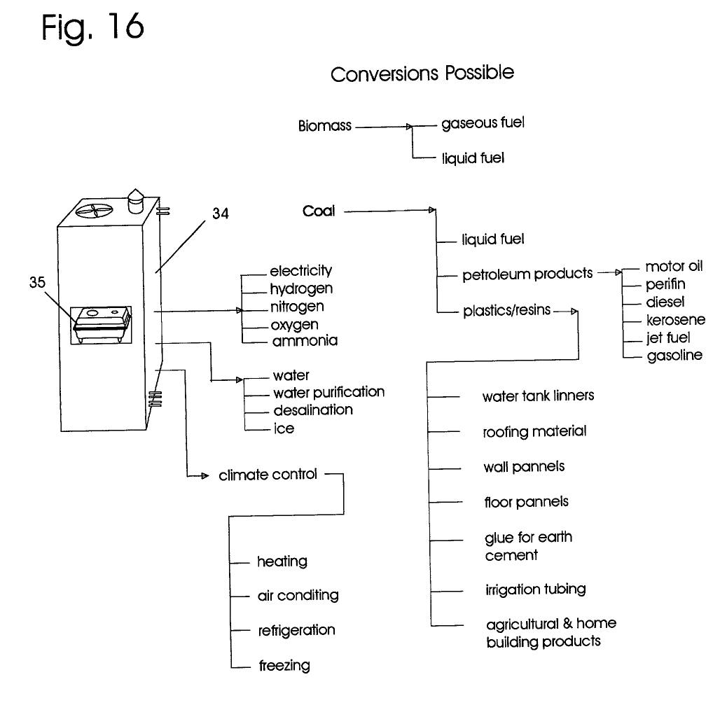

FIG. 13 illustrates how the invention 34 and generator 35 with fuel stream 55 can be used to cleanly reform coal into many useful products, one of which includes producer oil that can be burned cleanly in the invention. By using electrical energy produced from fuel stream 55, a water dissociation machine 61 can make hydrogen from water. Hydrogen supplied to reactor 70, which uses coal pulverized in process 71 using electrical connection 72 from 34. The pulverized coal is reacted in 70 using electrical connection 72 with a pressure of 2,400 lb/sq. in. and a temperature of 425 C. and hydrogen from 61. The reacted mixture is then transferred to reaction chamber 73 where it is dissolved in a special patented solvent as described in Exxon Pat. No. 5,584,989. The excess fluid is drained away and captured as producer oil, a fuel supply for the invention or a starting material for further refinement into many other useful and valuable products. In process 74, ash is removed from the product and this ash can be combined with building material that is a further invention described in FIG. 16. In 75, additional hydrogen is added from 61 along with electrical power through 72 to react the product at 2700 lb./sq. in. and at a temperature of 400 C. The final product of this reaction is purified producer oil from 76 at a temperature of 350 C. which can be returned to process 71 through loop 77 to combine with more pulverized coal to produce excess oil from reaction 70.

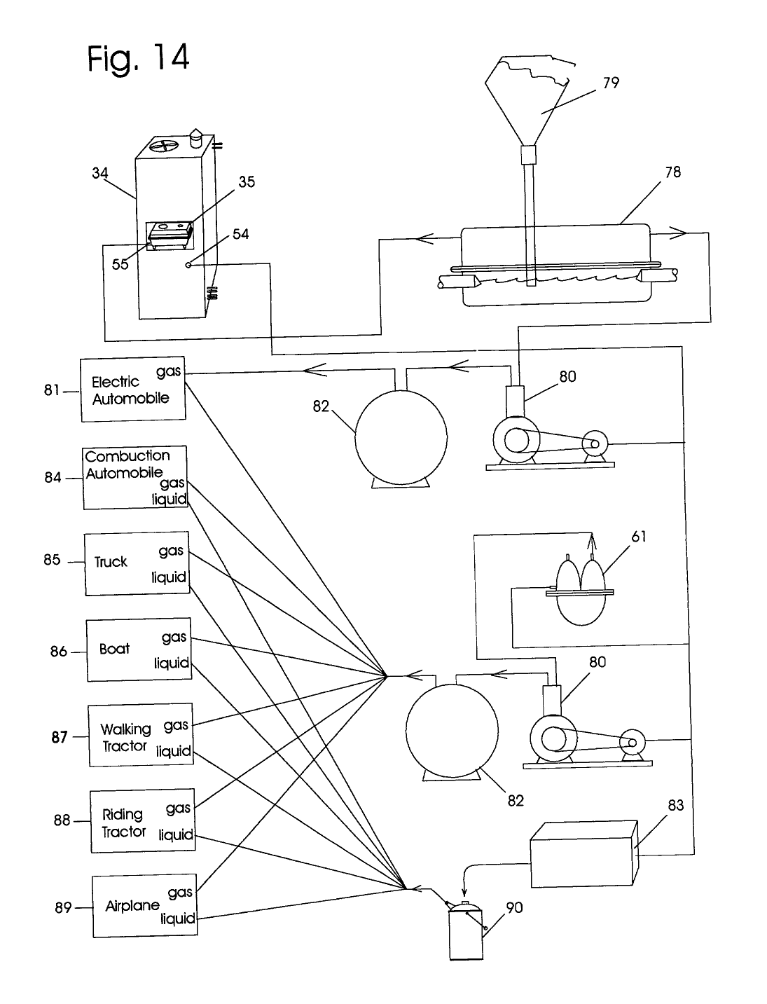

FIG. 14 illustrates how a biogas generator 78 operating on sewage, supplemented by animal waste 79 can supply the fuel stream 55 to the self-powered chiller invention 34 with generator 35. The biogas fuel stream can be pressurized by pump 80, that derives power from 54 of the self-powered chiller 34 with generator 35 to pressurize a fuel tank to power an electric-powered car 81, driven by a car mounted generator like 35. The fuel stream from pump 80 can also feed a self-powered chiller 34 with generator 35. Electrical connection 54 from a self-powered chiller 34 and generator 35, can drive pump 80 and also supply electricity to hydrogen machine 61. Pump 80 can store this hydrogen in a pressurized tank 82 until needed and transferred to electric car 81 as an alternate, renewable fuel source for transportation. Coal can also be converted in process 83 similar to the process described in FIG. 13. 83 makes producer oil and other liquid fuels such as diesel and gasoline suitable for use in many transportation means such as a combustion automobile 84, a truck 85, a boat 86, a walking tractor 87, a riding tractor 88 and an airplane 89. Liquid fuels 90 are more energy dense for transportation and are easier to store over long periods of time. The self-powered chiller invention can be used to run other parts of the invention to produce other forms of clean burning fuel in addition to the renewable fuel biogas 78. While producing different types of fuel, the invention can electrify and control the climate in a home, a village or industry, while using surplus of the single stream of heat source 55 to harvest and purify water.

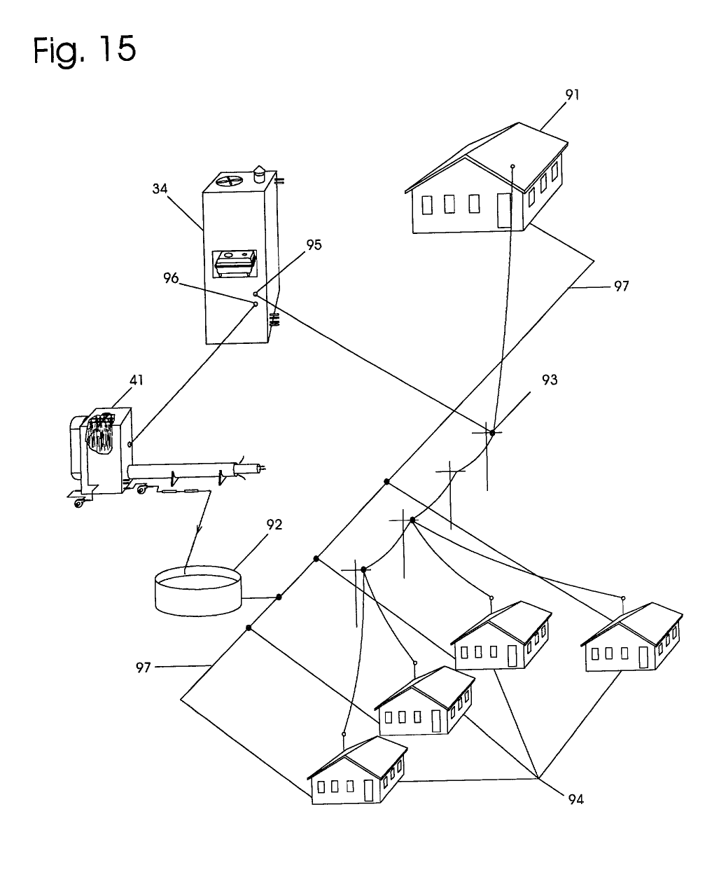

FIG. 15 illustrates one of the ways the invention 34 can supply electrical and climate control needs of a single household 91 while harvesting water from the air in device 41 and storing it in storage tank 92. In addition to this, the invention can supply electrical energy over the local grid 93 to neighboring homes 94 through electrical connections 95. Water, harvested from the air by device 41, or purified from either brackish or seawater by devices described in FIG. 11, and this water stored in tank 92 before being supplied to neighboring homes through pipes 97.

FIG. 16 diagrams how the self-powered chiller invention can be used to produce electricity, water, to purify water and make ice. In addition to this, the invention can use converted biomass into gaseous fuel to cleanly burn for operation. The invention can cleanly convert coal, the most plentiful and cheapest fuel on earth, into clean-burning liquid fuel that can be burned in the invention to make other gaseous fuels such as CH₄ and H₂ gas that are renewable and burn cleanly. FIG. 16 diagrams how coal can be reformed using the invention to convert them into all forms of petroleum products and plastics and polymer resins that can be used by the electrical component of the invention to make a variety of useful products. Products that can be reformed from coal using the invention include such items as irrigation tubing, water tank liners, roofing material roofing panels, trusses, wall sealer, flooring panels, and the adhesive for making cheap, interlocking building blocks and flooring out of dirt, for homebuilders in third world.

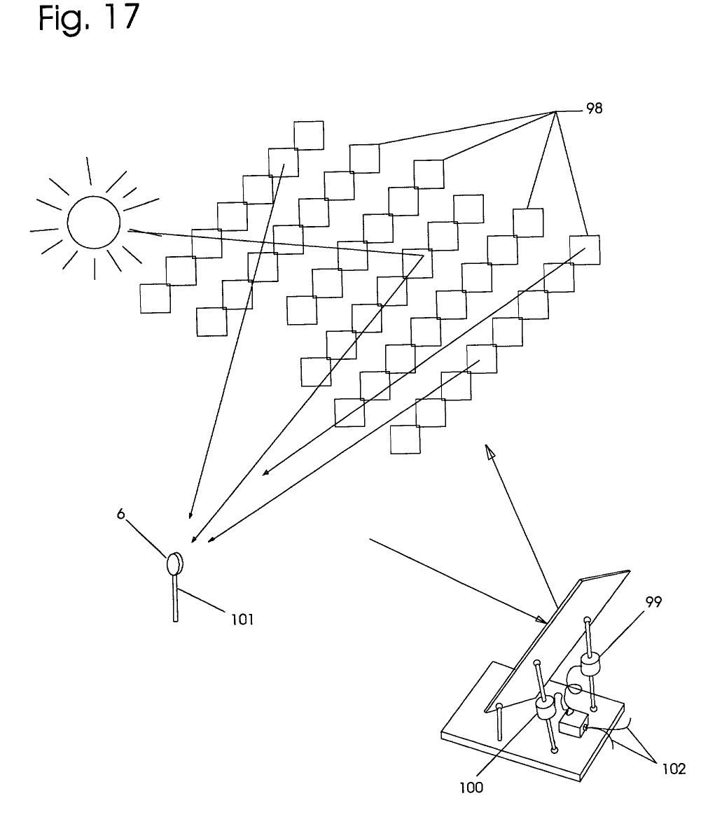

FIG. 17 illustrates a solar means of driving a thermoelectric generator 6 with a bank of smart reflecting mirrors 98. Each mirror is self-adjusting as situated randomly on the ground by electrical actuator 99 for latitude adjustments and for longitude adjustments to the mirror by electrical actuator 100, receiving signals from sensors mounted above and below and to either side of the generator ring of 6. Using the control system of 6, individual smart mirrors of FIG. 17 hunt for alignment between sun and the generator 6 so that each smart mirror can reflect reflected solar energy to heat the hot fins of generator 6. Generator 6 in a preferred embodiment is mounted on a stand 101 and placed to position hot fins so as to maximize the solar radiation from the smart mirrors. 102 shows a portion of the communication cable that connects each smart mirror with the control system of generator 6, which is specially configured to operate with solar energy. This invention is a cost-effective way to operate the generator 6 in areas where solar energy is plentiful.

It should be understood that many other arrangements can be made to concentrate solar energy onto the hot fins of the thermoelectric device. In a preferred embodiment the thermoelectric device is held at the focal point of a reflective dish. Said dish includes a means for tracking the sun so as to keep the concentrated solar energy focused on the hot fins.

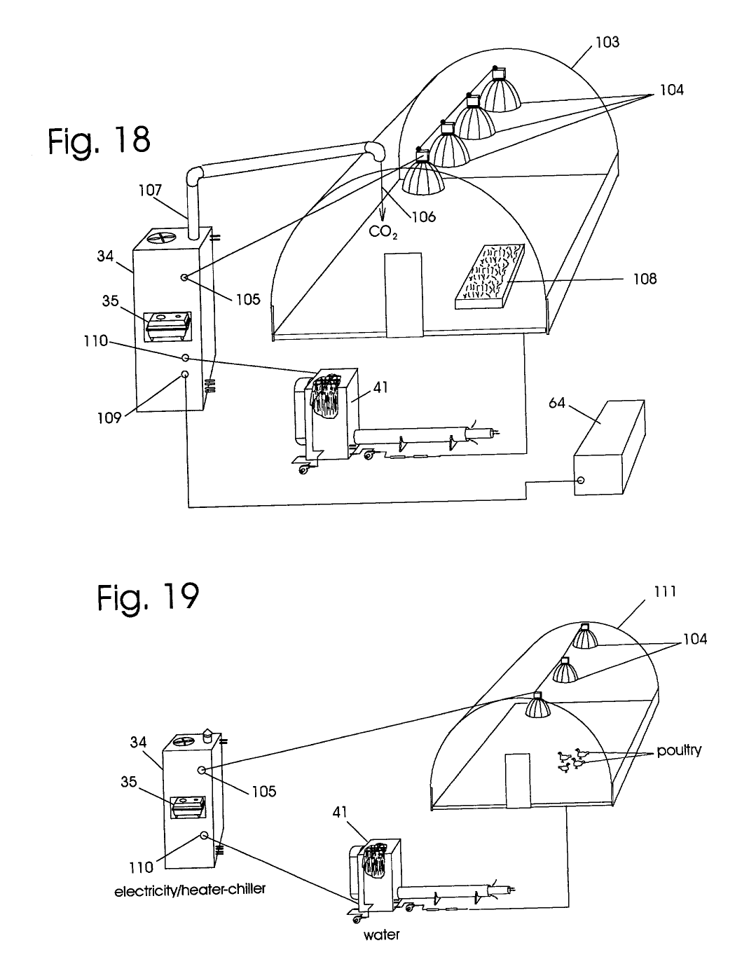

FIG. 18 illustrates a greenhouse grow farm 103 that utilizes the self-powered invention 34 and 35 to supply electricity to power grow lamps 104 through electrical connections 105. CO₂, 106 flows from the exhaust vent 107 of the self-powered chiller 34 to enter the greenhouse 103 and promote enhanced growth of plants in the greenhouse 103. The self-powered chiller can power an ammonia fertilizer appliance 64 through electrical connection 109, along with chill box 41 through electrical connection 110, each contributing to successful growth of plant and food in the greenhouse. This greenhouse can operate in all seasons because the self-powered chiller has the ability to heat and cool the greenhouse for optimum growth conditions, while supplying CO₂, fertilizer and water for the crop, regardless of season.

FIG. 19 illustrates a poultry farm for producing food on a year round basis using the greenhouse enclosure 111 like that of 103 in FIG. 18. The self-powered chiller 34 and 35 supplies electricity to power grow lamps 104 through electrical connections 105. The self-powered chiller 34 can harvest water from the air with dehumidifier 41, or purify water with a reverse osmosis 58 or electro-dialysis machine 56 to water the poultry crop. Additionally, a greenhouse of FIG. 18 can be used to grow food year round for the poultry farm 111. Both grow houses 103 and 111 contribute to the success of the other, manure providing biogas fuel for the self-powered chiller 34 and poultry providing fertilizer for the greenhouse, both operations able to operate year round regardless of weather conditions. The self-powered chiller's excess capacity can be used for meat processing, flash freezing and storage of crop before market.

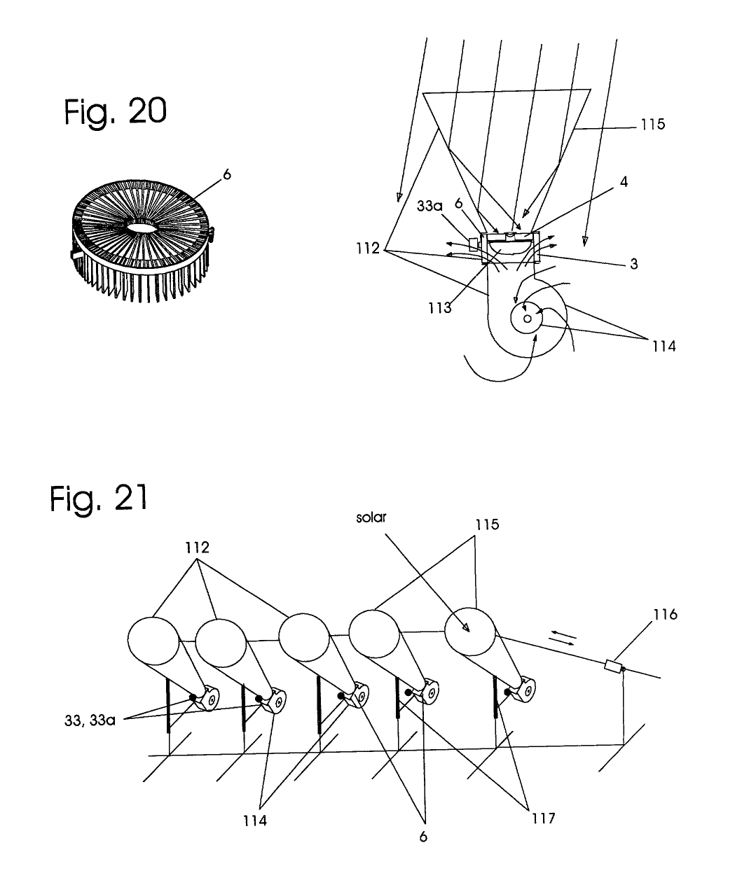

FIG. 20 illustrates how the ring of the generator 6 can be reconfigured to operate with solar energy. For terrestrial operation, the standard 6 ring is used as 112, less the burner bowl 14. A reflector bowl 113 replaces the burner. A motor with squirrel-cage blower 114 is mounted to pass air through the cooling fins 3. The motor and blower 114 blows air through cooling fins 3 so as to effectively cool the cold fins. On the hot fin side, a section of a cone 115 is fitted so as to gather and direct the solar energy to impinge on the hot fins 4. The cone system is not as sensitive to alignment with the sun as is a parabolic reflector, although a parabolic reflector can be used as well. With the cone 115 receiver method, any sunlight that enters the mouth of the cone, actually the cone's base, within 30 degrees of alignment, energy is directed to heat the hot fins 4 of the generator ring 6.

FIG. 21 illustrates how the tracking system 116, with assembled cones 115, rings 6, and blowers 114, need not be as precisely aligned to work effectively as a solar powered electric generator. The cone shades the cold-fin side of the ring and allows the fan to remove heat with ambient airflow, and thereby create the required 200 C. temperature differential, needed to operate the 112 generator at maximum power on solar heat. A 45 degree cone 115, with a small hole diameter of 7.5 inches to fit over the hot fins 3, and the cone's larger rim diameter would need to be about 8 ft. in diameter. This sized cone could collect enough solar energy to generate 3-kW output. The size could also be increased to produce the full 5-kW by simply lengthening the cone. The inner surface of the cone is made reflective for maximum solar reflecting efficiency. The surface or composition of the outside of the cone is not important to operation, but in the preferred embodiment, this surface is coated with a high temperature, all-weather coating such as fiberglass. The strength of the cone is important for all-weather structural considerations. The up-converter and control circuitry 33 and 33a are mounted in an EMI enclosure, containing ac and dc electrical output receptacles. The tracking hinges 117 are affixed about midway on the cone 115 so as to have a balanced movement for center of gravity and to counter wind loading.

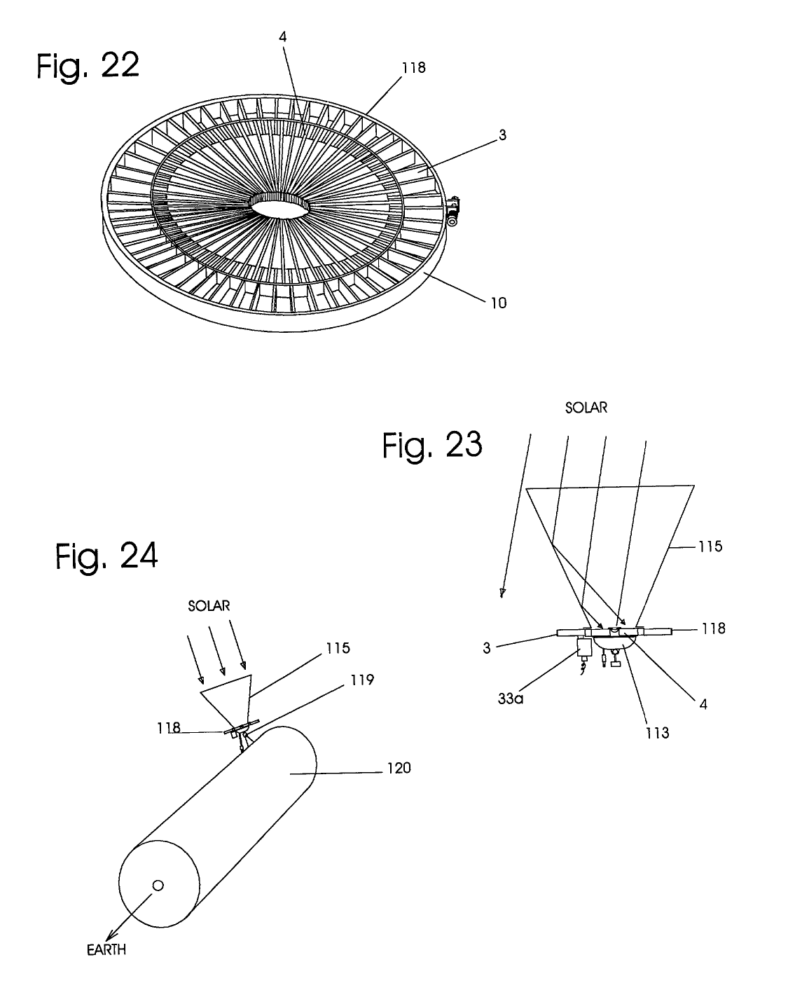

FIG. 22 illustrates a generator ring 6 configured as a space based, electrical power plant. The significant difference between 6 and 118 is in the positioning of the cold fins 3. The cold fins in FIG. 22, like the hot fins 4 are assembled in the same plane in the preferred embodiment. The cold fins 3 in the space version protrude outward from the current ring instead of pointing down as in FIG. 4, while the hot fins 4 remain pointing inward. This gives the structure the strength needed for long-term operation in space. An insulated strap 10 circles the outer tips of the cold fins 3, holding the assembled structure (the current ring section) in compression with the tensioned insulated strap 10.

FIG. 23 shows a generator that can be heated like the solar driven terrestrial model 112 in FIG. 20, although a much smaller receiver cone 115 is needed in space than for operation on the ground. Space solar radiation being much greater than on earth, and can be essentially continuous, a 5-kW generator in space might use a 5 to 10 sun collector with the open end of the cone pointed towards the sun. Heat radiation off the cold fins 3 on the dark side of the cone should be adequate to achieve a 200 C. differential between hot 4 and cold fins 3. This will produce a 5-kW heat flow through the 62 copper hot fins 4, into the 62 cold fins 3, by way of the thermoelectric material This configuration will have a very long lifecycle, compared to solar cells, and will be able to output high voltage ac as well as any level of dc voltage required. The mass of a 5-kW space generator is expected to be 5 kg, including the cone receiver, or a power to mass ratio of 1 kW/kg.

FIG. 24 illustrates the solar powered generator of FIG. 23 mounted on a swivel pointing mount 119 connecting to a satellite 120. FIG. 24 shows the generator of FIG. 23 pointing at the sun and one end of the satellite pointing at earth.

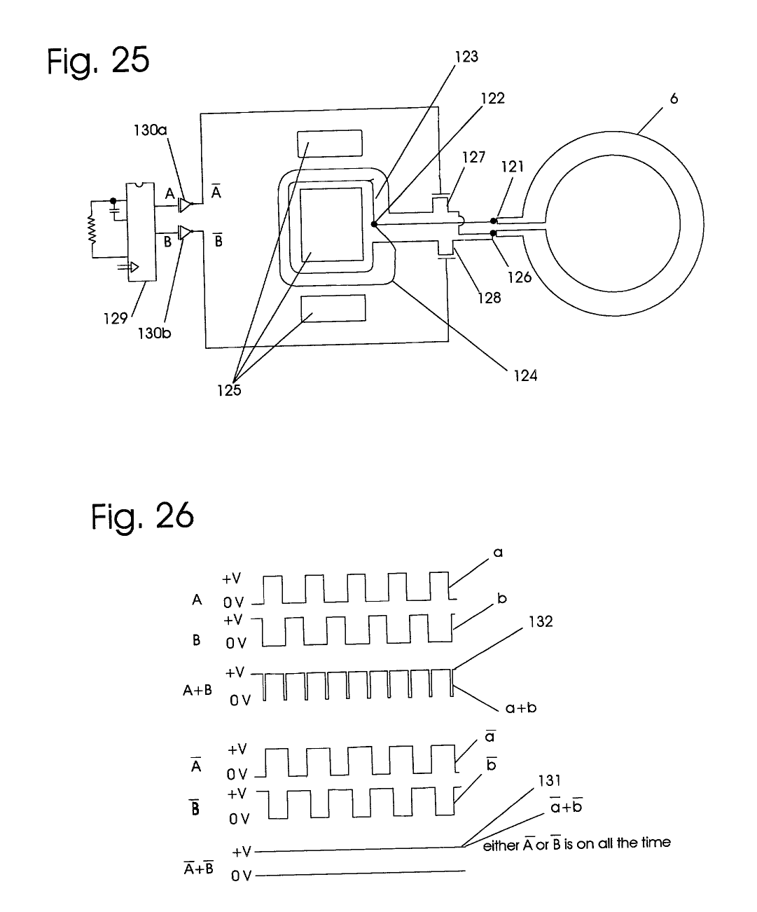

FIG. 25 illustrates the up-converter, which allows alternating current to be obtained from the low direct current voltage of ring 6 in FIG. 4. 121 is the positive lead of thermoelectric ring 6 and connects to the center tap 122 of a two turn primary winding 123 and 124 around a ferrite core, 125. In the preferred embodiment the center tap of the two turn primary winding is unbroken. Each end of the winding connects to negative terminal, 126, of the ring 6 with MOSfet switches, 127 and 128. A controller, pulse-width modulator chip 129, controls the opening and closing of the MOSfet switches, through MOSfet drives, 130a and 130b to make-before-break current paths back to the negative terminal 126. To work properly, the MOSfet drives 130a, 130b have inverted outputs, so as to allow the make-before-break feature. When the primary circuit is in alternate make-before-break mode there is no stopping of current in the thermoelectric ring therefore there is no need for current rise time in ring 6 and therefore no inductive spike or loss of power output from the ring. The switching frequency is between 50,000 and 200,000 hertz. This prevents saturation of a ferrite core 125, about which the two-turn primary 123, 124 is wrapped.

FIG. 26 illustrates the nature of the output voltage in the current mode prescribed 131 compared to non-inverted drive signals 132. In this inverted drive mode 131, the pulse width modulated control feature is maintained by a compensation of magnetic field rather than an interruption of magnetic field in the ferrite core 125.

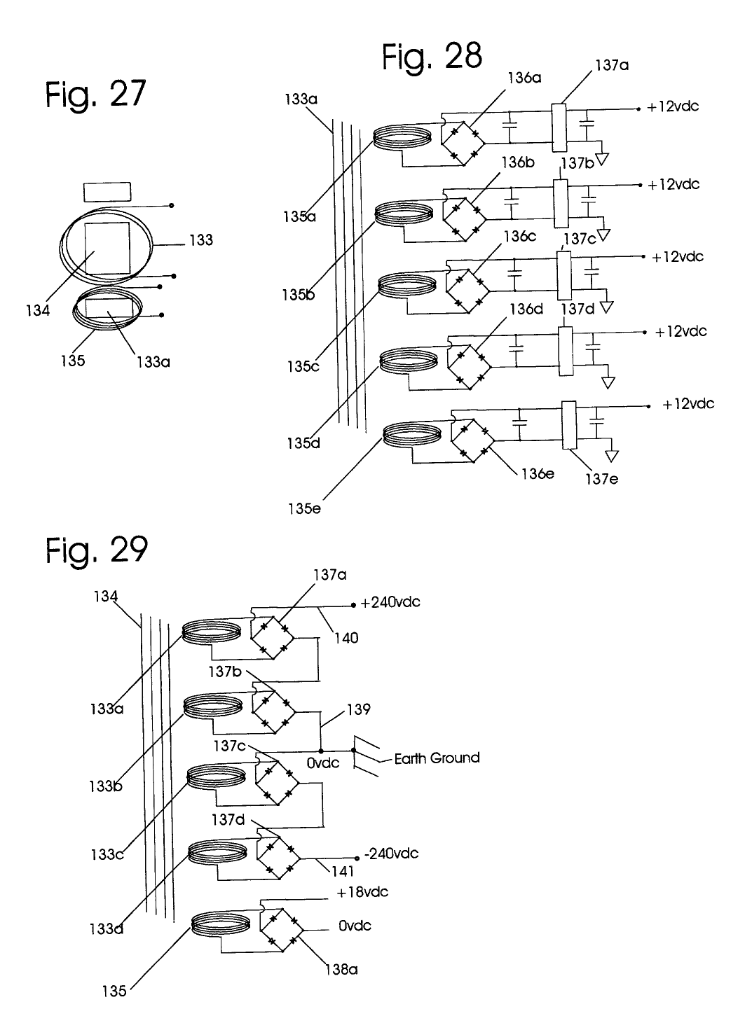

FIG. 27 illustrates the nature of the secondary windings 133. In the preferred embodiment multiple output ac voltages are obtained using one or more secondary windings around the ferrite core 134. The center stem of the ferrite core 134 has in addition to the primary windings, secondary multi-turn windings so as to increase the output voltage of the secondary. For example, 40 turns of secondary winding will produce 120 volts when 3 volts is produced in the primary winding. In a preferred embodiment, in addition to the other secondary winding 135 are one or more windings on one outer leg of the ferrite core 133a. To obtain the desired output voltages, the number of turns in the secondary around 133a requires two times more turns than if they were around the center stem 134 because field strength is only half that in the center stem 134 of the ferrite core. In preferred embodiment several separate windings are used to obtain isolated low voltage power sources for electronic control circuits.

FIG. 28 illustrates five separate windings, 135a, 135b, 135c, 135d and 135e, with separate full-wave bridge rectifiers 136a, 136b, 136c, 136d and 136e. The outputs of the bridge rectifiers input to separate +12-volt dc regulators, 137a, 137b, 137c, 137d and 137e. In a preferred embodiment +12 volt dc regulators 137a, 137b, 137c, 137d and 137e are used to drive separate control functions that need to be isolated from one another.

FIG. 29 illustrates a preferred output of 4 secondary high voltage output windings 133a, 133b, 133c, 133d, and one low voltage secondary winding 135. The low voltage output is used to supply power for control circuits. The output windings 135a-d collect high frequency ac power from the primary to secondary windings through the ferrite core 134, therefore each secondary winding 133a-d is rectified by full wave bridges 137a, 137b, 137c, and 137d to produce 120 volt dc outputs. Full wave bridge terminals are connected to obtain higher combined voltage outputs. In a preferred embodiment the output between bridge rectifiers 137b and 137c is taken to earth ground. Thus the voltage between earth ground and terminal 140 is +240 volts dc. The output between earth ground and 141 is −240 dc. Output 139 or 141 can be designated as electronic ground for the control system, or the ground for the control system can remain isolated, as the particular circuit requires.

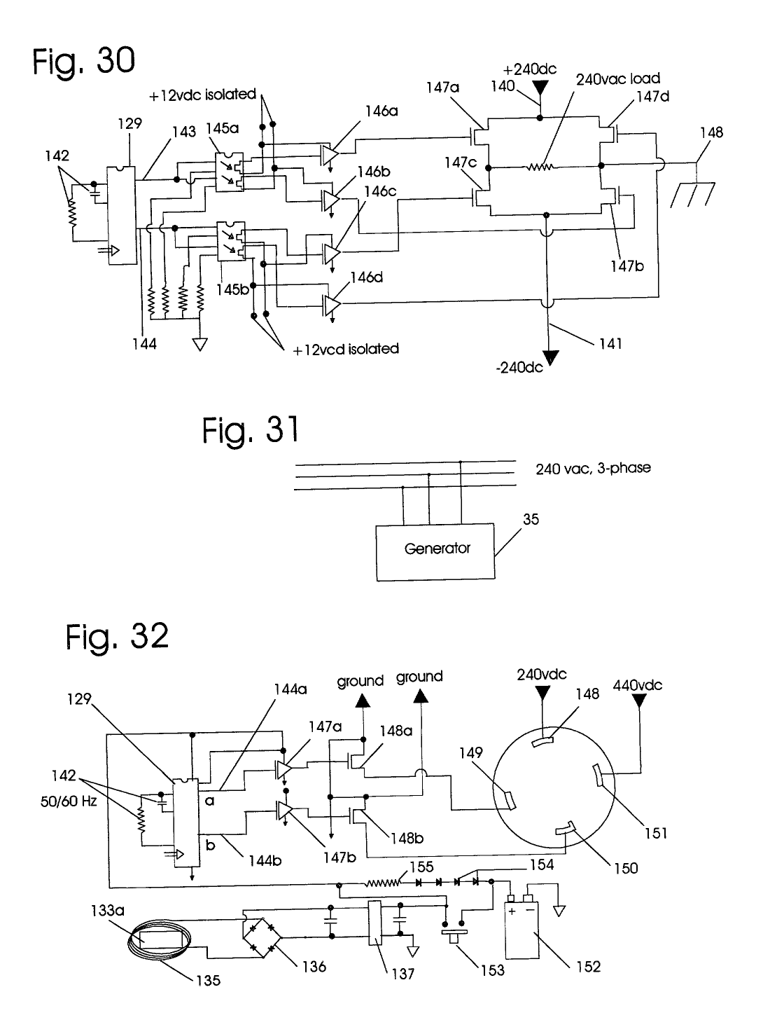

FIG. 30 illustrates a preferred embodiment using a pulse width modulator 129 tuned to operate at 50 or 60 Hertz by LC elements 142. Outputs 143 and 144 drive individual opto-isolating dual switches 145a and 145b. Each opto-isolator drives two MOSfet non-inverted drivers 146a-d. The power supplies for these drivers are each isolated power supplies of FIG. 28. The output of each MOSfet driver 146a-d is connected to one of 4 MOSfet switches, 147a-d, arranged as an H-bridge. One terminal, between MOSfet switches 147d and 147b of the H-bridge is connected to earth ground 148. The terminal between MOSfet switches 147a and 147d is the input from the +240 volt output of FIG. 29, bridge terminal 140. The terminal between MOSfet switches 147c and 147b is the −240 volt terminal 141 of FIG. 29. In FIG. 30, the 240 volt ac load terminals are between earth ground and between MOSfet switches 147c and 147a. The output load terminal for 110 vac is between terminal 141 and in between switches 147d and 147b, and also between 140 and earth ground. This arrangement provides a 240-volt output with two 120 vac splits.

FIG. 31 illustrates a 3-phase output arrangement that is realized by adding two additional MOSfet switches to the H-bridge and the appropriate 3-phase control circuitry. Higher numbers of phases are also possible and are advantageous for transportation applications where high starting torque is needed on traction motors.

FIG. 32 illustrates a preferred embodiment of a limited version of the output signal processing shown is FIG. 30. A pulse width modulator 129 is driven by a regulated power supply, 137 generates a regulated 12-volt dc output for all chips of the circuit. Regulated power supply 137 derives its power from a full-wave bridge 136 that is powered by a coil 135 around the leg 133a of the ferrite core 134 of FIG. 27. The pulse width modular 129 output 144a drives a non-inverting MOSfet driver 147a and the 144b output of the pulse width modulator 129 drives a non-inverted MOSfet drive 147b. MOSfet driver 147a drives MOSfet switch 148a. Switch 148a switches ground to socket terminal 149. A 120 vac load can be connected between socket terminal 148 which is connected to +240 vdc and socket terminal 149 which is switched to ground. The pulse width modulator chip 129 is set to operate at a frequency of 50/60 Hertz by LC elements 142. The load across terminals appears to the load as a 120 vac power supply. MOSfet switch 148b connects ground to socket terminal 150. The 220 vac load is connected across terminals, 150 and 151 which is connected to +440 vdc. The load across terminals 150 and 151 appears to be driven by a 220 vac power supply. In fact, this power supply is a simple on-off supply operating in the on mode as the full peak-to-peak voltage of 240 vdc and 440 vdc supply. The uniqueness of this variant is in the very few parts that are required to make it operate. The loads are powered alternately for half of the 50/60-Hertz cycle and the circuit is open alternately for the other half of the cycle providing a quasi-square-wave drive. Current is intermittent for the other half of the cycle. The simplicity of this circuit favors reliability under rugged operating conditions. All chips have a common low voltage ground. All chips have common regulated 12-volt dc power from regulator 137. This architecture simplifies the control circuitry. For initializing the circuit a rechargeable 9-volt battery 152 is used with its ground connected to electronic ground. The positive terminal is connected to a momentary-on electrical switch, 153 and then connected to the common 12 volt bus. Four diodes 154 are in series across momentary switch 153 with a 1000-ohm resistor 155. The anode ends of the diode string are connected to the plus terminal of the battery to form a current limiting battery charging circuit when the ferrite core 133a is active. To start the output signal processing circuit the momentary switch 153 is pressed allowing all elements of the circuit to be energized directly from the battery 152. When the momentary switch is released the power supply 137 is active and because core 133a is active this operates the pulse width modulator chip 129 and charges the battery 152 from coil 135 through the diode string 154 and resistor 155. In preferred embodiment the momentary switch is pressed about 20 seconds after the generator burner of the device is ignited. After the momentary switch 153 is released, current from regulated 12-volt dc 137 can then recharge the 9-volt battery 152 through the diode string and resistor. Resistor 155 limits current and voltage across the string, reduced by the diodes, drops to 1.2 volts higher than the battery's nominal 9 volts.

FIG. 33 shows another preferred embodiment where the device utilizes power from a circle of coupons, ring 6, as it heats up to generate from 0.1 to 3.0 volt output, converting it into five or more isolated, 12 vdc power supplies, to power all element of the control circuit as shown in FIG. 28.

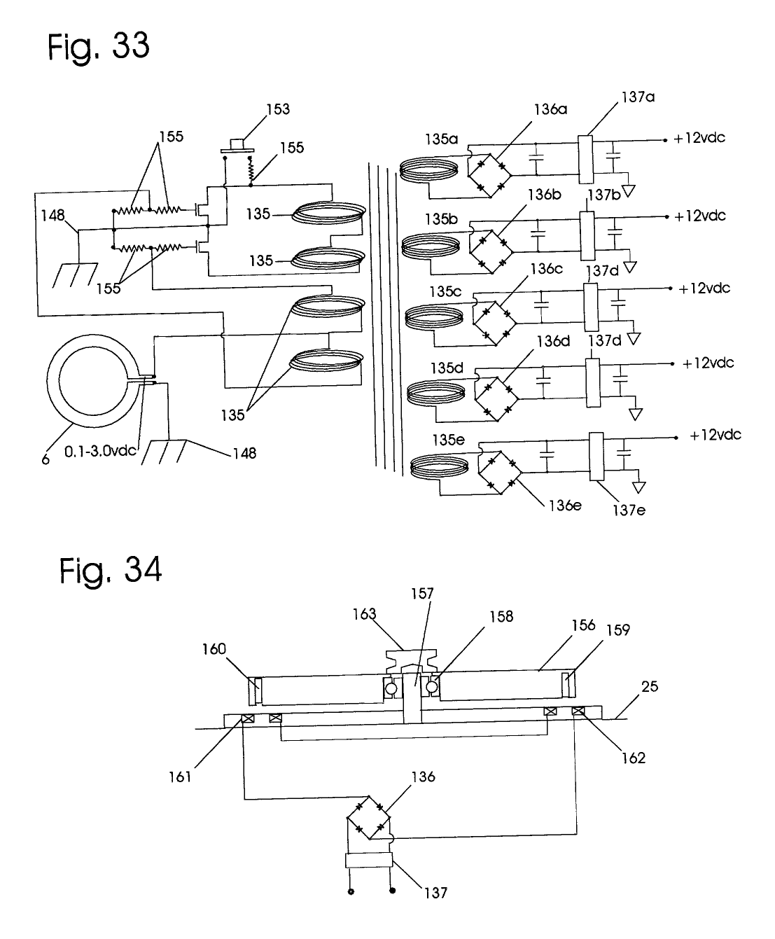

FIG. 34 shows another preferred embodiment where the circuit is initiated by manual means. A flywheel 156 is fitted to a shaft 157 by means of a bearing 158. The flywheel has magnets 159 and 160 with vertical poles in opposite directions. Beneath the flywheel are coils 161 and 162 series connected to full-wave bridge 136. A pulley 163 is attached above the flywheel 156. A string can be wrapped about the pulley and when the string is pulled the flywheel 156 spins with the magnets 159 and 160 energize coil 61 and 162 inducing a current in the full Wave Bridge 136. Enough current is produced to drive the voltage regulator 137 supplying regulated power to the circuit of FIG. 32 as well as the high frequency drive circuit in FIG. 25, 30 and 32.

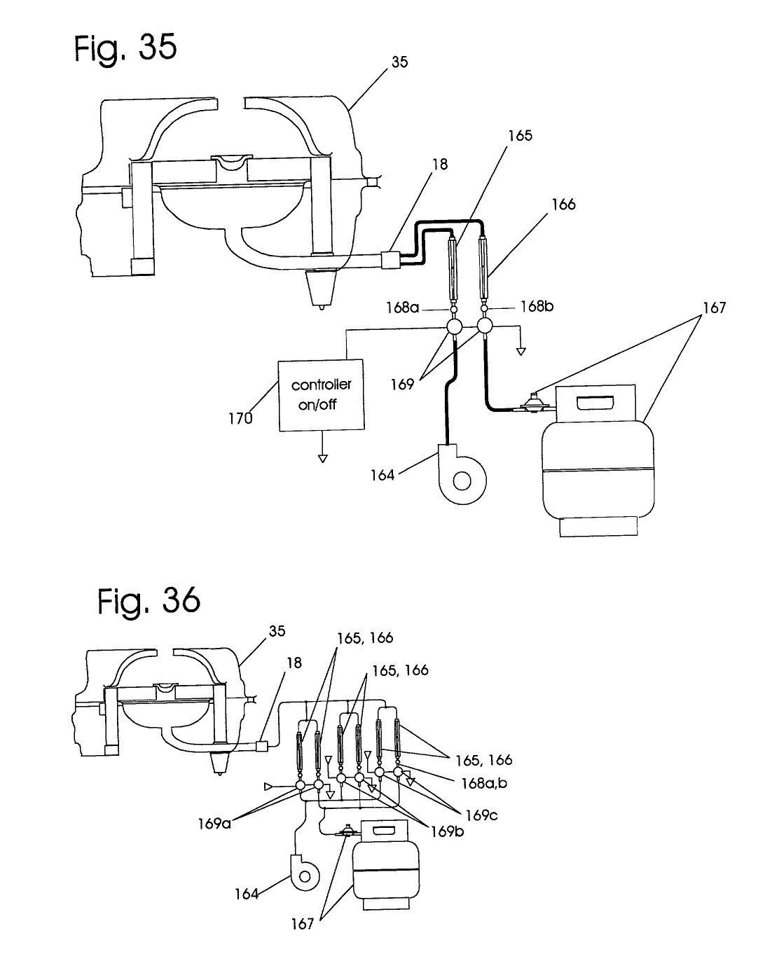

FIG. 35 illustrates a control system for generator and applications. The basic heat control system for the generator was described in FIG. 6 where a high-pressure stream of fuel, metered through an orifice 30 induces air to mix with the fuel in a 14-16 to one mixture to insure proper combustion. Ignition of the fuel-air mixture above the burner and beneath the hot fins of the generator causes heat from the flame to heat fins 4. This is a manual system with higher fuel flow, causing more heat, lower flow less heat above the burner screen 16. The control invention allows the generator to be electronically controlled on and off. A high-pressure air induction system in the form of an air blower 164 supplies air to burner pipe 18. The air supply is metered through a valve 168a and flow meter 165 and into this air supply, fuel is metered by flow meter 166 into the pressurized air-stream in burner pipe 18 from a pressure regulated fuel source 167 through a metering orifice 168b into the air supply. Electrically operated control valves 169 connected electrically in series are used to turn the metered air and fuel supplies on or off as the electronic control system 170 demands. This is an on/off system that can be operated with manually preset flow rates in anticipation of generator loading.

FIG. 36 illustrates another variant that uses a pressurized air supply blower 164 and a pressurized fuel supply from a regulated pressure source 167 feeding through pairs of valves 169 a-c feeding flow meters 165, 166 that allow an adjustment of air-fuel with valves 168a-b adjusting mixture and total flow of the fuel-air mixtures for each pair of control features that can be controlled on/off by electronic means.

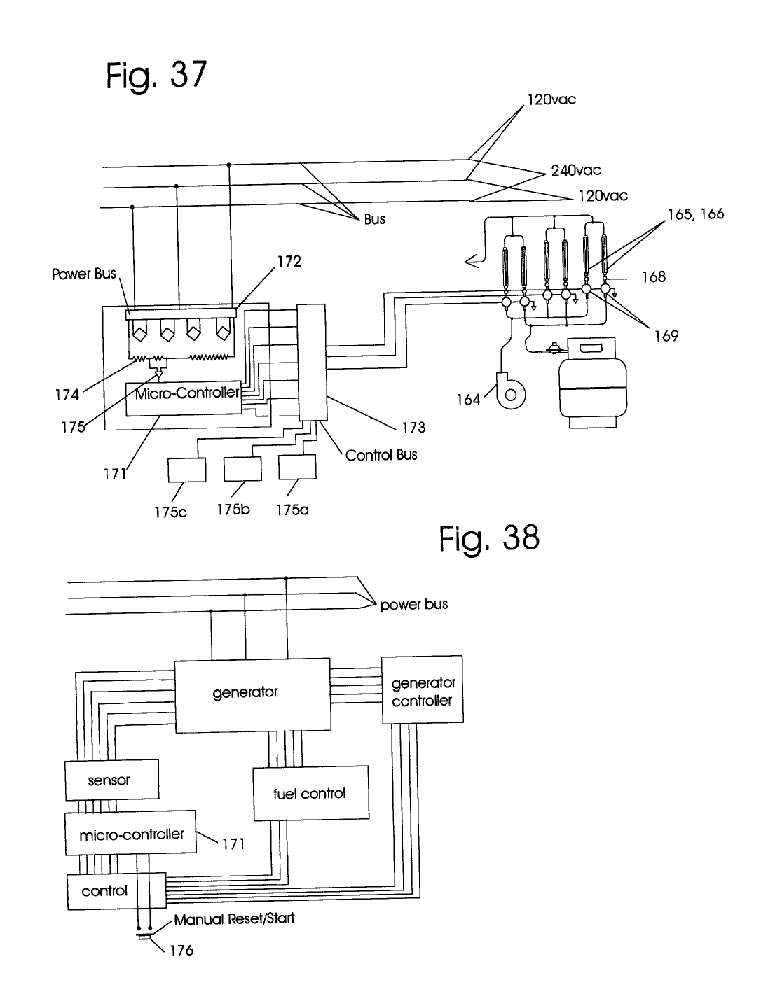

FIG. 37 illustrates a means to achieve fuel modulation by electronic control for bus voltage regulation due to electrical loading of the generator. This variant uses pairs of air-fuel valves 169 with adjustment valves 168 under individual flow meters sets 165, 166, the first set adjusted to supply heat for 17% of generator output capacity, the second set to 34% output capacity and another set adjusted to 51% of output capacity. By electronically selecting combinations of the three (or more) valve sets 169a-b, the generator's fuel input can be adjusted to produce no output (all valve pairs off) or 17% with the first pair only on, 34% with the second pair on, 51% with the third pair on, 68% with the first and third pairs on, 85% with the second and third pairs on and 102% with all valve pairs on. Valve pairs can be selected by a micro-controller 171, monitoring voltage on the output bus 172, programmed so as to use the least amount of fuel to maintain output voltage above a preset value (˜220 vac) but controlling 173 below an upper bus voltage (˜240 vac). This is achieved by controller 173 selection of none, or any combination of just three valve pairs 169a-c. This feature allows the generator to burn the least amount of fuel while maintaining output voltage between predetermined limits. By selecting all three valve pairs a 102% fuel flow can be achieved, or a combination of “on” and “off” valve pairs allows fuel burn to more closely match or slightly surpass that needed for electric production between output voltage limits, including all off when no electric production is needed. By using only three valve pairs in combination, fuel-air flow can be adjusted for output power and can be controlled by the micro-processor 171 to burn the least air-fuel needed to maintain line voltage on the output bus 172 within preset limits, to follow load variations on the bus. A high temperature sensor 175a, located on cover 19 of FIG. 6 above the hot fins 4, senses for over-temperature and instructs the micro-controller 171 to shut off all air-fuel valve pairs to the burner when there is an over-temperature condition. A temperature sensor 175b, located on one of the cold fins 3 allows the micro-controller to sense an over-temperature of the voltage producing junctions, possibly because the cooling fan has failed, and the micro-controller causes a shut-off of all fuel-air mixture valves 169 to the burner in an over-temperature condition. A resistor ladder 174 across the power bus 172 is used to divide the voltage across the dc side of the power bridges, fed by high frequency power from the generator's up-converter shown in FIG. 25. As a part of the resistor ladder, voltage reference signals, adjusted with a manually set or computer set potentiometer, feed into a differential operational amplifier 175 that is set to send an interrupt signal by the micro-controller 171 to interrupt the operation of the pulse-width-modulator chip 129 when bus voltage falls below a preset limit and this inhibits the operation of the up-converter drive shown in FIG. 25. The potentiometer is pre-set to an arbitrary value of say 100 Volts. If the loading on the power bus increases to cause the output of the generator to fall below 100 Volts, the generator's micro-controller 171 off-switches the load, shuts off the air-fuel supply, and the control system goes into shut-down mode. The power bus 172 is disabled but the cooling fan motor 32 in FIG. 7 continues to run for an additional 3 minutes to cool the voltage producing portion of the generator ring 6 to prevent undue stress on the generator. Should the output current exceed the rated capacity of the generator for more than one second, a current sensing chip 175c, a differential operational amplifier across a shunt in series with an output power leg, is connected to cause an interrupt of the pulse width modulator chip 129 in FIGS. 25, 30 and 32. This event triggers a shutdown of the output power from the generator.

FIG. 38 diagrams the control system. This system is configured to shut down the air-fuel mixture valves 169 but continues the power to the cooling fan motor 32 so as to prevent generator thermal stress. To restart the generator, the operator can manually restart with switch 176 after determining the cause of the over current and waiting 3 minutes, going through the manual restart procedure for the generator. The control system 171 can also be programmed to attempt to restart the generator automatically, after performing internal diagnostics to determine the cause of the over current before reconnecting to the load

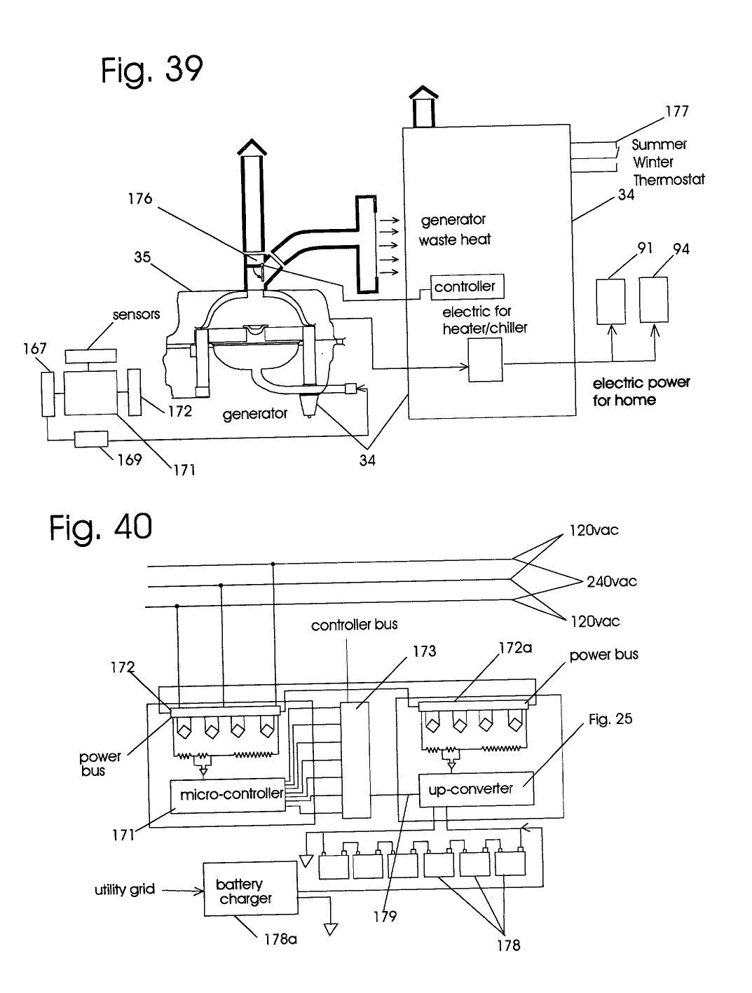

FIG. 39 illustrates a generator, configured to operate as a power supply for a heat powered, heater-chiller system 34, with unique controls illustrated in FIG. 37 that allow it to operate as a seamless alternative to the power grid. When the heater-chiller 34 is switched on, the generator is auto-started by micro-controller 171 to be in the “on and ready” mode; ready to supply the power needed to operate the heater-chiller 34. The heater-chiller then has electric power and heat from the generator's exhaust switched-in by valve 176 directed by micro-controller 171 to begin refrigeration or heating operations. The heater-chiller is under the control of a thermostat 177 that determines the mode in which the heater-chiller will operate and whether it needs to operate to satisfy interior climate control requirements of the home 91. The air-fuel mixture and quantity of heat supplied to the generator is controlled by the micro-controller 171 to operate with just enough electrical output capacity to satisfy the electrical power for the heater-chiller. It can also be programmed to produce enough energy to satisfy the needs of other appliances in the residence 91 and that of other residences 94, or a commercial building. The electrical power level of the generator is adjusted by micro-controller 171 by sensing the voltage across the dc output bus 172, the micro-processor adjusting air-fuel supply valves 169 to control near the center of an adjustable preset bus voltage range. Should the bus voltage rise above the nominal preset voltage level, the micro-controller 171 selects air-fuel valve 169 sets that lower or decrease burn rate to achieve and control at a nominal, preset output bus 172 voltage. The same heat that exits the generator, normally wasted exhaust gas, is diverted to pass through and operates the heater-chiller 34. A solenoid actuated diverter valve 176 in the exhaust stream of the generator 35 directs exhaust heat either through the heater-chiller, or to exit to ambient when the heater-chiller requires no heat. In this way, the heater-chiller's standard control system can call for heat with the same controls and power source that was used to open the now redundant gas valve that previous to this implementation of this invention fueled the unneeded burner in the heater-chiller. When the heater-chiller's thermostat 177 calls for heat, the solenoid activates diverter valve 176. No separate fuel supply is needed to operate the heater-chiller; the generator's diverted exhaust being adequate for operation.

FIG. 40 illustrates a means to make the small generator operate as if it were much larger in capacity. An up-converted, similar to the one described in FIG. 25, is driven by a bank of batteries instead of thermoelectric ring 6. This system can be connect to the generator's power bus 172 to help support the bus loading when the generator is overloaded. A bank of batteries 178, for example about six car batteries, driving a push-pull up-converter with dc bridges can be connected by control line 179 to allow the generator and battery bank work together to output power when the output bus is overloaded. The battery bank connects when the bus falls below a lower voltage limit than the generator maintains. The battery bank's power bus 172a and the generator's power bus 172 are connected in parallel to power the H-bridge driving the ac output bus. The two systems can operate independently or the two can work together, instantaneously allowing the generator to operate as if it had a twice larger output power capacity for several minutes until the battery bank depletes. The tying of the two systems, generator and battery, together at the dc bus is novel. When the power bus is pulled lower than the preset value that the generator controller tries to maintain, the battery system is connected by program to come on line to hold the bus above a preset voltage level, otherwise the bus voltage would be pulled lower by the increased loading. The battery boost system, working in conjunction with the generator, will allow the generator to operate at near the minimum bus voltage, with minimum fuel burn, yet be able to respond to instantaneous bus loading with the aid of the battery boost. Should the generator run out of fuel, the battery boost could support the load until fuel supplies can be replenished. This is another benefit of the thermoelectric battery hybrid.

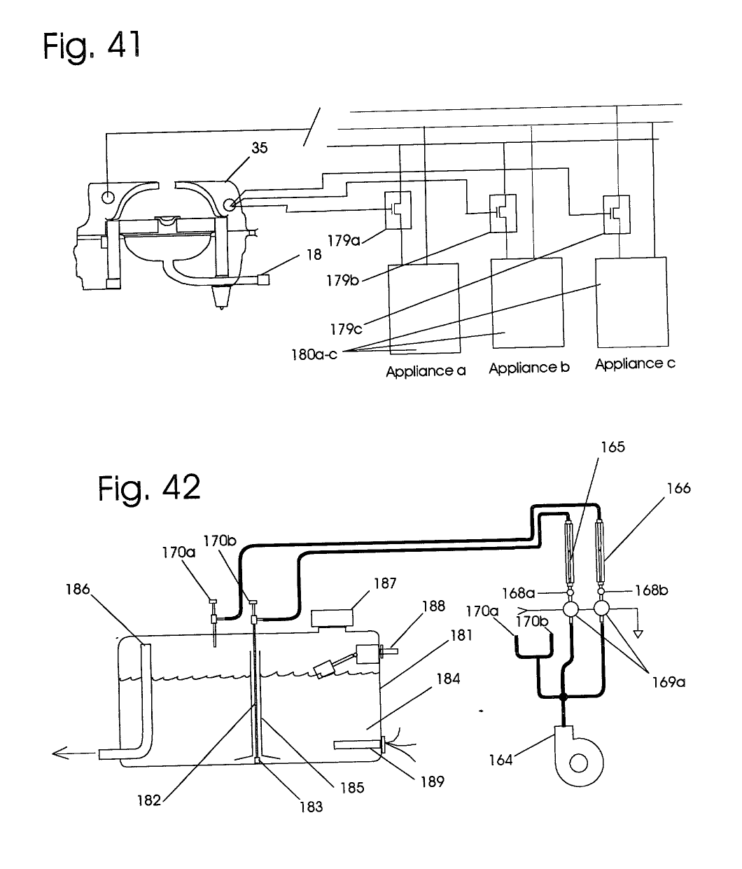

FIG. 41 illustrates a smart switch that can drop off loading in an overload condition, or delay the start of a new load until the generator's voltage and power output capacity can be restored, powered up to assume the new load. The smart switch is helpful to give the generator advanced warning, that a power up is needed by an appliance, when the generator is operating in economy mode, or is in the off mode, before a new load is assumed through a smart switch.

FIG. 42 illustrates a carburetor to burn all forms of liquid fuel in the thermoelectric generator. A blower 164 supplies pressurized air to flow meters 165 and 166 metered by valves 168a and 168b to enter tank 181. Metered air from flow meter 165 enters tank 181 through tube 182 and bubbling frit 182, below liquid fuel 183. Atomized air-fuel mixture rises inside of bubble tube 185 to exit at the top of tank 181. Pressurized air from blower through flow meter 165 enters the top of the tank to mix with the atomized air-fuel mixture. The mixture exits tank 181 at the top of tube 186. Tube 186 connects to burner pipe 18 to supply metered air-fuel mixture to generator 35. The same control system described in FIGS. 35, 36 and 37 are used to control air-fuel supply to generator 35 making liquid fuel version electronically controllable as with gaseous fuels. Tank 181 is a small tank that is easily portable with pressure cap 187. 188 shows a float valve that receives fuel from a larger fuel tank flowing by gravity feed or pumped. Cartridge heater 189 with thermostatic control is used to heat fuel for better atomization of heavy fuels in cold arctic climates. In a preferred embodiment gas instead of air is pumped into the carburetor to create a more combustible mixture of combined fuels. For low voltage applications such as electro-dialysis desalination, current is used at the voltage provided by ring 6 without conversion through leads on each side of the insulator 9. For higher direct current applications voltage is increased by primary and secondary windings where the primary winding leads are attached to each side of the insulator 9 through cold fin terminals 7 and 8.

A preferred embodiment uses hot fins coated with a combustion catalyst when combustion occurs at or near the hot fins.

The n-type and p-type semiconductors play an important role in allowing high conversion efficiency. Example 1 gives the range of elements and a preferred amount of elements making up the n-type semi-conductor. Example 2 gives the range and preferred amount of the p-type semiconductor.

### EXAMPLE 1

n-type Semiconductor Composition

| Element | Range | Preferred Amount |
|---|---|---|
| Selenium | 5%-10% | 6% |
| Bismuth | 40%-60% | 47% |
| Tellurium | remainder to 100% | 47% |

### EXAMPLE 2

p-type Semiconductor Composition

| Element | Range | Preferred Amount |
|---|---|---|
| Antimony | 28%-30% | 29.1% |
| Bismuth | 8%-10% | 9.5% |
| Tellurium | remainder to 100% | 61.4% |

Copper and other elements greatly degrade performance of these semiconductor components therefore high purity elements are preferred. Each chemical element should be at least 99.9% pure and preferably 99.999% pure. In a preferred embodiment said elements are combined and melted to a temperature of about 700 degrees before being cast into a desired shape.

Slow cooling of the combined elements makes high quality semiconductors. A preferred size for the wafers is 1.5 mm thick by 2-cm by-2 cm. For ease of presentation the 2-cm by 2-cm sides are called faces and the 1.5-mm×2-cm sides are called “sides”. To achieve slow cooling combined melted semiconductor material is pour into a mold of the desired shape having the thin direction cast vertically, that is, sides are facing horizontally. In a preferred embodiment the wall of the mold is coated with hollow ceramic spheres obtained from fly-ash material that floats on water. The ceramic spheres are in the form of a powder that has relatively uniform size of less than 10 microns. Preferably the powder is held together in the mold by propylene glycol or milk of magnesia. In a preferred embodiment cast faces of the semiconductor are lightly smoothed using a belt sander with 100-grit aluminum oxide sandpaper. Properly cast wafers have a crystal grain size that microscopically appears to approach 2-mm. Transfer of electrons across the semiconductor is improved when some portions of the semiconductor are without a boundary barrier in the direction of flight of the electrons.

Semiconductors are protected from infiltration of copper atoms and components of solder by coating them entirely with a thin layer of nickel, ranging from 1 to 10 microns thick. The edges of the semiconductors are further coated with a non-conducting insulator to reduce heat conduction not progressing through the fin. In a preferred embodiment the coating is a high temperature polymer, such as Tempilaq, manufactured by Air Liquide America Corp. of South Plainfield, N.J. 07080, USA. The sides of the semiconductor are further coated with an additional thickness of nickel of at least 20 microns, preferably 20 to 30 microns.

In a preferred embodiment fins are made of copper. To reduce corrosion and prevent migration of copper into the semiconductor the fins are coated with metal more resistant to oxidation, preferably nickel. In a preferred embodiment the fins are tapered on the opposite end connecting to the semiconductor to allow complete metal filling of the circle. In another preferred embodiment the ends of the hot fins facing the center of the circle are tapered to reduce the likelihood of an electric short caused by fins touching.

An alternative approach to achieve uniform metal-semiconductor filling of the circle is to have straight ends on the fins and to insert coated copper wedges periodically around the circle. Preferably the copper wedges are coated with nickel and placed in registry with each coupon.

A single insulator is placed in the ring and preferably an additional cold fin with adjacent semiconductor. In a preferred embodiment the insulator is made of mica.

Placing solder between the surfaces of the fins and the semiconductors completes assembly the thermoelectric device. Preferably prior to assembly solder is applied to both sides of the hot and cold fins at a thickness of between 50 and 100 microns. Kester's solder is preferred but an additional 4% of silver needs to be added for optimal performance.

A considerable outward radial force occurs when heat is applied to the hot fins and current flow in the torus. To prevent collapse of the device compressive force needs to be supplied. This is accomplished by tightening a metal strap around the device. To prevent shorting by the metal strap and insulating material is place around the ring before attaching the metal strap. Preferably the insulating wrapping is heat shrinkable polyimide. In another preferred embodiment the steel band is held in compression using one or more Belleville disk spring washers. These allow compression to be retained when the device cools. Non-metallic thermo-stable plastic can be used in lieu of a metal band with electrical insulator.

Prior to assembly each coupon is tested for its thermoelectric activity.

After assembly and application of inward compression by the metal ban the device is heated. In a preferred embodiment the rate of heating is 10 degrees per minute to a temperature of 270 degrees C. The device is removed an allowed to cool in air. In another preferred embodiment the cold fins are positioned downward so any excess solder drips along the cold fins creating extra surface area for heat exchange.

A variety of controls can improve the utilization of stand-alone and hybrid version of the thermoelectric device. For example, a self-powered climate control system can power the electrical needs of the residence or a commercial building, while operating a heat-powered heater-chiller system with generator exhaust heat and a small portion of the generator's electrical production. There will be times when either electrical or heating-chilling will be surplus. To make the most economical use of the surplus capacity, an air dryer, which is a machine that wrings water from air can be incorporated to supply drinking, sanitary and agricultural water for residents and for community uses. Under certain atmospheric conditions, 1,000 gallons and more can be harvested from the air, making use of the self-powered generator-chiller, especially during the nighttime, and periods of high humidity. This is also a time when electrical and chilling demands can be lower; so excess capacity can be utilized for water production using any or all of the water production means described.

A micro-controller can be set to optimize the production of electricity, heating or chilling or for water making during nighttime hours. The control system consists of a selector knob that is positioned to cause the system to operate within preset limits with fuel economy, low operating cost, and to prioritize chilling capacity during the day, switching to water production during nighttime hours. What this selector does is tell the micro-controller to concentrate on holding parameters that would enhance the system's operation in the selected mode, holding the operational parameters of the other operations to a looser specification. In other words, if water production is emphasized, and all the other systems will operate at 100 vac and the environment is comfortable at 80F, the system will be adjusted to operate at most economical conditions to produce water and support the other operations with a more relaxed specification.

The Generator's control system will seek the lowest fuel burn to maintain a preset voltage level on the bus. This is the most efficient way to operate the generator, to consume the least amount of fuel for electrical production. There are many occasions where the load on the line will increase dramatically and will require the generator to be operating at a much higher fuel burn to support the loading. Because the generator requires a recovery time between the time the increased loading is applied and the time required for the generator come up to the increased output levels (about 30 seconds), the dimming of house lighting will signal the application of increased loading. This is disconcerting to the user. With the utility grid, this is taken care of with spinning reserve at the generation site, and the fact that the grid system is huge and is not easily affected with the switching in of a mere household load. With smaller stand-alone generation, the sudden addition of a significant load causes the house lights to dim for a period until the generator can increase the heating to assume the extra loading at the previous voltage level. One way to instantaneously increase the effective power of the generator is to allow the up-converter controller to switch from producing a sine wave to a square wave. This is done until the heat can be raised in the generator, then the waveform can revert back to the sine wave at the previous voltage. Since the square wave has almost 30% more energy than a sine wave, this is a practical way to make a little generator, operating with maximum fuel efficiency, react instantaneously (in a few microseconds) to maintain bus voltage in spite of the increased loading. This waveform change allows the generator to operate as if it has a 30% spinning reserve. This way, it can support the previous load and a load that is 30% higher at constant voltage, until the burn rate can be increased. It can support this loading without allowing the lighting to dim or cause detriment to any of the loads. Another way this feature can be used is to set the generator control system to operate producing only a square wave, and thereby saving 30% of the fuel that would otherwise be consumed in producing a sine wave. The lights may dim but saving 30% on fuel bills may be worth this minor annoyance. The user has clear choices as to how this system operates, the cost of operation, and what is more important.

In a preferred embodiment a Smart Switch is installed at the site of each large electric load, such as an electric stove, electrically powered air conditioner, or electric clothes dryer. The Smart Switch communicates with the generator to signal that a large load is in the “on” mode. The Smart Switch delays the switching on of the appliance until the generator signals that particular Smart Switch that it has increased the output (fuel burn) to accommodate the new loading. When the generator's micro-controller signals the Smart Switch that it has increased capacity to assume the load, the Smart Switch switches the appliance onto the bus. The generator's control system constantly monitors output capacity and can maintain this extra capacity until the work of the extra loading is completed, then reducing fuel bum to a minimum level to support bus voltage within preset limits. If however, another Smart Switch signals to come on line, and the burner is at maximum fuel burn, the generator's micro-controller may delay the start of the new load until another load drops off the bus or there is adequate output capacity available. The Smart Switch signaling the load size to the generator's controller for this determination. In this way, a small capacity, highly efficient generator can serve the same function as the grid, by delaying the start of certain appliances. Also, certain Smart Switches can be programmed to have higher priority over other Smart Switches, delaying the clothes drying for instance in favor of cooking supper on the stove, resuming the drying operation after a meal is cooked.

In another preferred embodiment the battery boost allows the system's micro-controller to shut off the generator at night when loading is below a certain load level, only to restart the generator when the batteries drain to a lower and preset safe level. The battery system can be charged with energy from the grid or with electrical energy from the generator. By using the utility grid to charge the battery bank, this usage prevents the utility company from abandoning the customer when running exclusively on the self-powered generator-chiller system. Another benefit to the user, should the generator system ever fail, the utility service can be used as if nothing happened, bring in outside energy through the battery system through charging. On the other hand, should the utility system fail, the generator can support the residence or commercial building as if there no power failure occurred, automatically and without disconnects or switchovers. This will provide the user with seven 9 s reliability, up from the standard four 9 s reliability realized with the grid only. This is why it is important for the customer to remaining connected to the grid when it is available. By using the grid only for charging the battery bank, not only are the batteries maintained, the residence or commercial building will realize a source of emergency power for a small monthly minimum charge, and the facility will have the seven 9 s reliability required for dependable computer operation.

The above described inventions and implementations illustrate the broad range of uses of the improved thermoelectric device and its hybrid versions. In addition there are may other implementations which utilize the valuable properties of these inventions including efficiency, low noise and portability.

In a preferred embodiment a smaller version of the thermoelectric device described in detail herein is made to be a backpack generator. By providing 120 vac output the backpack can be used with any tool or device which would otherwise require proximity to an electric outlet or portable liquid-fuel stand-alone generator.

In another preferred embodiment a thermoelectric device as illustrated and claimed herein is combined with the mechanical portion of a tool producing a thermoelectric tool. Examples include but are not limited to a chainsaw, circular saw, reciprocating saw, drill, posthole digger, and automatic nail driver.

In a preferred embodiment the thermoelectric device claimed herein is combined with a mechanical compressor and air storage chamber to provide a portable, quite and efficient air compressor system.

In another preferred embodiment a small thermoelectric device is fitted to replace batteries in battery powered hand tool systems, especially those that use a common battery size and shape to power a variety of different tools.

In another preferred embodiment a small thermoelectric device is designed to be affixed commonly to mechanical portions of common hand tools. In one case the electrical output drives an electric motor used to power the mechanical portion of the tool. The benefit of having a hybrid tool is to allow the energy demand of the tool to control the fuel consumption rate by direct feedback.

In addition to thermoelectric tools the thermoelectric device disclosed here can replace other means of supplying energy to appliances. Thus a thermoelectric device can be used to power a compressor in a common household refrigerator of freezer. Similarly an electric stove can be powered by gas or liquid fuel by utilizing a thermoelectric device. Such appliances fitted to burn wood would be especially useful in remote areas where wood is abundant and electricity is not present. As with thermoelectric tools thermoelectric appliances have the benefit of allowing feedback to control the rate of combustion.

In another preferred embodiment a thermoelectric powered chiller and water harvesting machine is designed to be affixed to the outside of an apartment, townhouse, condo or the floor of an office to provide electricity, climate control and water independent of the buildings services, needing only a fuel supply. Such a system will make retrofit of existing facilities easier providing an alternative to high cost, unreliable utilities and nuclear source power in Europe and elsewhere in the world.

Thus having described the method of manufacture of components, the assembly of components, an efficient means to extract energy produced by a temperature differential, a means to improve the overall efficiency of converting heat to electricity by combining said thermoelectric device with a chiller and by having given a variety of examples as to how to combine said thermoelectric with other components to provide a broad range of useful products, we claim:

We claim:

1. An improved closed circuit thermoelectric device with n-type and p-type Seebeck components comprising:
(a) a plurality of coupons placed in registry in a circle separated by a single insulating segment, each coupon comprising a metallic hot fin an adjacent n-type semiconductor, on the opposite side from the n-type semiconductor of said hot fin a p-type semiconductor and consistently adjacent to either the n-type or p-type semiconductor a metallic cold fin;
(b) a means for heating said hot fins;
(c) a means placed across said insulating segment to remove electrical energy generated from said circle of coupons when heat is applied to said hot fins.
(d) a means for holding said plurality of coupons in compression.

2. A device according to claim 1 further comprising:
(e) a means to cool cold fins.

3. A device according to claim 2 wherein said means to cool cold fins is blown air

4. A device according to claim 2 wherein said means to cool cold fins is: placing said cold fins in water”.

5. A device according to claim 2 wherein said means to cool cold fins is: pumping cold air or cold fluid over said cold fins.

6. A device according to claim 1 wherein said metallic hot fins and said metallic cold fins are made of copper and coated with nickel 25 microns or less thick.

7. A device according to claim 6 wherein said hot fins are further coated with a combustion catalyst.

8. A device according to claim 1 wherein said n-type semiconductor and said p-type semiconductor are coated entirely with a nickel layer about 10 microns thick and the faces of said semiconductors are further coated with additional nickel to a thickness of at least 20 microns.

9. A device according to claim 7 wherein the edges of said semiconductors are further coated with a thermal and electrical insulator.

10. A device according to claim 1 wherein said n-type semiconductor of said device is made of selenium in an amount of from 5% to 10%, bismuth in an amount of 40% to 60% and the remainder percentage tellurium.

11. A device according to claim 10 wherein said elements comprising said semiconductor are of purity of at least 99.9%.

12. A device according to claim 10 wherein said n-type semiconductor is made by mixing granular or powdered constituents in the desired ratio, heating to about 700 degrees centigrade, pouring said mixture into a mold of desired shape and allowing said semiconductor to cool slowly.

13. A device according to claim 12 wherein said mold is lined with hollow, sintered ceramic spheres of size less than 10 microns diameter obtained from fly-ash particles that float on water.

14. A device according to claim 1 wherein said p-type semiconductor of said device is made of bismuth 8% to 10%, antimony 28 to 30% and the remaining percentage tellurium.

15. A device according to claim 14 wherein the purity of said elements of said semiconductor is at least 99.9%

16. A device according to claim 14 wherein said p-type semiconductor is made by mixing granular or powdered constituents in the desired ratio, heating to about 700 degrees centigrade, pouring said melted elements into a mold of desired shape and allowing said mixture to cool slowly.

17. A device according to claim 16 wherein said mold is lined with hollow, sintered ceramic spheres of size less than 10 microns diameter obtained from fly-ash particles that float on water.

18. A device according to claim 1 further comprising a modified Kester's solder containing an additional 4% silver wherein said solder is applied prior to assembly to each side of said hot fins and said cold fins to a thickness of between 50 to 100 microns.

19. A device according to claim 1 wherein said fins are rectangular and adjacent to each set of hot fins, cold fins, n-type semiconductor and p-type semiconductor of the coupon is inserted a copper wedge coated as in claim 2 the dimension of said wedge is adjusted to allow circular assembly of said coupons.

20. A device according to claim 1 further comprising an insulating wrapping surrounding the circular portion of the assembled coupons.

21. A device according to claim 20 wherein said insulating wrapping is made of heat shrinkable polyimide.

22. A device according to claim 1 wherein said means for holding said assembly in compression is a high tensile strength strap which can be tightened to circularly compress an assembly of coupons.

23. A device according to claim 22 wherein said high tensile strength strap is made of steel of thickness less than 5 mm.

24. A device according to claim 23 wherein said steel strap is further fitted with one or more Belleville disk spring washers that maintain compression upon cooling.

25. A device according to claim 1 wherein said hot fins and said cold fins are arranged at between 45 degrees and 225 degrees relative to one another.

26. A device according to claim 25 wherein an assembled thermoelectric device with cold fins between 45 and 160 or between 200 and 225 degrees has been heated in an oven with said cold fins downward at temperature rate of 10 degrees minute to 270 degrees C., then allowed to cool.

27. A device according to claim 1 wherein said heating means is gas burner vented to pass over said hot fins.

28. A device according to claim 1 wherein said heating means is a focused beam of sunlight.

29. A device according to claim 1 wherein said heating means is steam.

30. A device according to claim 1 wherein said heating means is combusted liquid fuel.

31. A device according to claim 30 wherein liquid to be combusted is combined with a gaseous fuel to optimize overall combustion.

32. A device according to claim 1 wherein said heating means is combusted solid fuel including but not limited to coal, wood and other biomass.

33. A device according to claim 1 further comprising a metallic or ceramic screen place below said hot fins said screen to have a melting temperature above 900 degrees centigrade and opening size of less than 2 mm cross section.

34. A device according to claim 1 wherein said hot fins are arranged facing inward to the center of said circle and a insulating plug is placed so as to cover the opening between the fins forcing heated air between said fins.

35. A device according to claim 1 further comprising a heat reflecting crown above said hot fins said reflecting crown having a section cut back or cut out to allow escape of hot gas.

36. A device according to claim 35 wherein said heat reflecting crown is insulated on its side opposite the source of heat.

37. A device according to claim 1 further comprising a blower to control air intake for improved combustion.

38. A device according to claim 1 wherein said means to remove energy from said heated thermoelectric device is a up-converter comprising bi-directional primary windings around a ferrite core, a means to rapidly switch current flow of the primary windings, and single or multiple secondary windings.

39. A device according to claim 38 wherein said means to switch current direction in said primary windings is a plurality of semiconductor gates controlled by a high frequency circuit, said high frequency circuit comprising a method involving make-before-break commutation of switching currents which eliminates transmission spikes retaining the pulse-width-modulation feature for voltage stabilization of the output through feed-back from a voltage ladder on the secondary side of the circuit to the pulse-width-modulator controller-driver.

40. A device according to claim 39 further comprising a means to provide electricity to initially drive said up-converter.

41. A device according to claim 40 wherein the means to provide electricity to initially drive is one or more batteries.

42. A device according to claim 41 further comprising a switch and direct current input to allow the up-converter to be used to produce alternating current from exterior direct current sources.

43. A device according to claim 1 further comprising a switch and means to take direct current directly from across said insulator.

44. A device according to claim 1 further comprising a means to ignite fuel to be burned.

45. A hybrid thermoelectric-chiller device comprising said thermoelectric device of claim 1 and a chiller wherein exhaust heat is transfer to said chiller to produce cooling.

46. A device according to claim 45 wherein chilled air or liquid from the chiller is circulated to the cold fins of the thermoelectric component to improve heat to electricity conversion.

47. A device according to claim 46 wherein a portion of chilled air or liquid from the chiller is used to condense fresh water from air.

48. A device according to claim 45 wherein some of the heat of combustion is channeled to said chiller without passing the hot fins of the thermoelectric component.

49. A device according to claim 45 further comprising a water-harvesting machine.

50. A device according to claim 45 wherein electricity generated from the thermoelectric component is used to freeze water that is cooled by the chiller.

51. A thermoelectric device according to claim 1 designed and sized to be fitted as a backpack.

52. A thermoelectrically driven conveyance.

53. A thermoelectrically driven tool or appliance.

54. A thermoelectrically drive tool according to claim 53 wherein said tool is comprised of a dc drive tool and a thermoelectric device producing dc power.

55. A tool according to claim 53 wherein ac voltage from a thermoelectric component drive a motor that produces the mechanical energy needed by the tool.

56. A tool according to claim 53 wherein fuel consumption of said thermoelectric component is regulated by feedback form the mechanical component.

57. An appliance according to claim 53 wherein said appliance is fitted with a means to signal that power is needed by the appliance.
